(19) United States
(12) Patent Application Publication
(10) Pub. No.: US 2015/0091084 A1
(43) Pub. Date: Apr. 2, 2015

(54) POWER MOSFET DEVICES INCLUDING EMBEDDED SCHOTTKY DIODES AND METHODS OF FABRICATING THE SAME

(71) Applicants: Heon-Bok Lee, Suwon-si (KR); In-ho Yeo, Seoul (KR); Sae-Choon Oh, Seoul (KR); Suk-Kyun Lee, Yongin-si (KR); Jung-ho Lee, Incheon (KR)

(72) Inventors: Heon-Bok Lee, Suwon-si (KR); In-ho Yeo, Seoul (KR); Sae-Choon Oh, Seoul (KR); Suk-Kyun Lee, Yongin-si (KR); Jung-ho Lee, Incheon (KR)

(21) Appl. No.: 14/323,731

(22) Filed: Jul. 3, 2014

(30) Foreign Application Priority Data
Sep. 27, 2013 (KR) 10-2013-0115473

(51) Int. Cl. H01L 29/78; H01L 29/66

(52) U.S. Cl. CPC H01L 29/7806; H01L 29/66712; H01L 29/66143
USPC 257/334; 438/270

(57) ABSTRACT

A semiconductor device can include first and second vertical channel power MOSFET transistors that are arranged in a split-gate configuration in a semiconductor substrate. A groove can be in an active region between the first and second vertical channel power MOSFET transistors and a conductive pattern can be in the groove on the active region, where the conductive pattern can include a source contact for the first and second vertical channel power MOSFET transistors. A vertical Schottky semiconductor region can be embedded in the groove beneath the conductive pattern between the vertical channels.

### CROSS-REFERENCE TO RELATED APPLICATION

This application claims priority under 35 U.S.C. §119 to Korean Patent Application No. 10-2013-0115473 filed on Sep. 27, 2013, the disclosure of which is hereby incorporated by reference in its entirety.

### BACKGROUND

1. Field

Embodiments of the inventive concept relate to a semiconductor device, a method of fabricating the same, and an electronic system including the same.

2. Description of Related Art

Power MOSFETs may be used in a power supply set or a power-variable application system. In order to reduce power consumption of a device or system including the power MOSFET, various methods are being studied.

### SUMMARY

Embodiments according to the inventive concept can provide power MOSFET devices including embedded Schottky diodes and methods of forming the same. Pursuant to these embodiments, A semiconductor device can include first and second vertical channel power MOSFET transistors that are arranged in a split-gate configuration in a semiconductor substrate. A groove can be in an active region between the first and second vertical channel power MOSFET transistors and a conductive pattern can be in the groove on the active region, where the conductive pattern can include a source contact for the first and second vertical channel power MOSFET transistors. A vertical Schottky semiconductor region can be embedded in the groove beneath the conductive pattern between the vertical channels.

In some embodiments according to the inventive concept, the first and second vertical channel power MOSFET transistors can be arranged in the split-gate configuration to operate as a single transistor. In some embodiments according to the inventive concept, the device can further include a drain contact for the first and second vertical channel power MOSFET transistors beneath the groove opposite the source contact.

In some embodiments according to the inventive concept, the vertical Schottky semiconductor region and the conductive pattern can be an embedded vertical Schottky diode that forms a junction at a bottom of the groove with the active region. In some embodiments according to the inventive concept, the vertical Schottky semiconductor region can include 13th and 15th group elements of the long-form Periodic Table, and an amount per unit volume of the 15th group element that can be greater than that of the 13th group element in the Schottky semiconductor region.

In some embodiments according to the inventive concept, the device can further include first and second source regions for the respective first and second vertical channel power MOSFET transistors, where the first and second source regions can be on opposite sides of the groove, and where the source regions can include lowest most implanted regions that are above the junction.

In accordance with an aspect of the inventive concept, there is provided a semiconductor device. The semiconductor device includes an epi-semiconductor substrate. A semiconductor layer is disposed on the epi-semiconductor substrate. Trenches are disposed in the epi-semiconductor layer defining an active region. A groove region is disposed in an upper surface of the active region. The groove region isolates first and second active protrusions of the active region. A gate structure is disposed in each of the trenches. A front-side conductive pattern filling the groove region is disposed. A first conductivity-type drift region, first and second body channel regions having a second conductivity-type different from the first conductivity-type and spaced apart from each other, and first and second source regions having the first conductivity-type and spaced apart from each other on opposite sides of the groove region, are disposed in the active region of the semiconductor layer. The first conductive-type drift region, the first and second body channel regions, and the first and second source regions form a transistor with the gate structure. A Schottky semiconductor region is disposed between the first and second body channel regions in the groove and in the active region under a bottom surface of the groove region. The Schottky semiconductor region forms a Schottky diode with the front-side conductive pattern.

In some embodiments, the Schottky semiconductor region may include 13th and 15th group elements of the long-form Periodic Table, and the amount per unit volume of 15th group element may be greater than that of 13th group element in the Schottky semiconductor region.

In other embodiments, the drift region adjacent to the Schottky semiconductor region may include the same amount per unit volume of 15th group element as the Schottky semiconductor region, and the drift region may include a higher majority carrier concentration than the Schottky semiconductor region.

In still other embodiments, the first source region may be disposed in the first active protrusion, and the second source region may be disposed in the second active protrusion. Bottom surfaces of the first and second source regions may be located at a higher level nearer to the groove region than nearer to the trench region.

In still other embodiments, the first and second body channel regions may be disposed on the drift region, the first source region may be disposed on the first body channel region, and the second source region may be disposed on the second body channel region. The first and second body channel regions may have P-type conductivity, and the drift region, the Schottky semiconductor region, and the first and second source regions may have N-type conductivity.

In still other embodiments, the Schottky semiconductor region may include 13th and 15th group elements of the long-form Periodic Table, and the amount per unit volume of 15th group element may be greater than that of 13th group element in the Schottky semiconductor region. The first and second body channel regions may include 13th and 15th group elements of the long-form Periodic Table, and the amount per unit volume of 15th group element may be smaller than that of 13th group element in the first and second body channel regions. The drift region adjacent to the first and second body channel regions and Schottky semiconductor region, the first and second body channel regions, and the Schottky semiconductor region may each include equal amounts per unit volume of group element.

In still other embodiments, the semiconductor device may further include a first body contact region disposed in the active region between the conductive pattern and the first body channel region, and a second body contact region disposed between the conductive pattern and the second body channel region and spaced apart from the first body contact region. The first and second body contact regions may have a higher majority carrier concentration than the first and second body channel regions adjacent to the first and second body contact regions.

In still other embodiments, the front-side conductive pattern may form ohmic contacts with the first and second body contact regions and the first and second source regions.

In still other embodiments, a bottom of the Schottky semiconductor region may be disposed in a constant depth form the surface of the active region.

In still other embodiments, each of the first and second protrusions may have a lower width greater than an upper width.

In still other embodiments, the gate structure may include a gate electrode in which an upper portion has a greater width than a lower portion, and a gate dielectric layer interposed between the gate electrode and the active region.

In still other embodiments, the semiconductor device may further include an insulating capping pattern disposed on the gate structure.

In still other embodiments, the insulating capping pattern may include a first insulating capping pattern, a second insulating capping pattern, and a third insulating capping pattern. The second insulating capping pattern may be interposed between the first and third insulating capping patterns and formed of a different material from the first and third insulating capping patterns.

In still other embodiments, the insulating capping pattern may overlap the gate electrode, and upper surfaces of the first and second active protrusions.

In still other embodiments, the semiconductor device may further include an insulating buffer pattern disposed between the insulating capping pattern and the gate electrode, and between the insulating capping pattern and the active region, and having a smaller thickness than the gate dielectric layer.

Details of other embodiments are included in the detailed description and drawings.

### BRIEF DESCRIPTION OF THE DRAWINGS

FIGS. 1A and 1B are views showing a semiconductor device in accordance with an embodiment of the inventive concept;

FIG. 2 is a view showing a semiconductor device in accordance with another embodiment of the inventive concept;

FIGS. 3A and 3B are views showing a semiconductor device in accordance with still another embodiment of the inventive concept;

FIG. 4 is a view showing a semiconductor device in accordance with still another embodiment of the inventive concept;

FIGS. 5A and 5B are views showing a semiconductor device in accordance with still another embodiment of the inventive concept;

FIG. 6 is a view showing a semiconductor device in accordance with still another embodiment of the inventive concept;

FIGS. 7A to 7V are views showing a method of fabricating a semiconductor device in accordance with an embodiment of the inventive concept;

FIGS. 8A to 8E are views showing a method of fabricating a semiconductor device in accordance with another embodiment of the inventive concept;

FIGS. 9A to 9D are views showing a method of fabricating a semiconductor device in accordance with still another embodiment of the inventive concept;

FIGS. 10A to 10C are views showing a method of fabricating a semiconductor device in accordance with still another embodiment of the inventive concept;

FIGS. 11A to 11C are views showing a method of fabricating a semiconductor device in accordance with still another embodiment of the inventive concept;

FIG. 12 is a view showing a method of fabricating a semiconductor device in accordance with still another embodiment of the inventive concept;

FIG. 13 is a schematic circuit diagram illustrating semiconductor devices in accordance with embodiments of the inventive concept;

FIG. 14 is a block diagram illustrating electronic systems including the circuit of FIG. 13; and

FIG. 15 is a block diagram illustrating electronic systems including the system of FIG. 14.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art.

The terminology used herein to describe embodiments of the invention is not intended to limit the scope of the invention. The articles “a,” “an,” and “the” are singular in that they have a single referent; however, the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the sizes and relative sizes of layers and regions may be exaggerated for clarity. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In the following explanation, the same reference numerals denote the same components throughout the specification.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation.

It will be understood that, although the terms first, second, A, B, etc. may be used herein in reference to elements of the invention, such elements should not be construed as limited by these terms. For example, a first element could be termed a second element, and a second element could be termed a first element, without departing from the scope of the present invention. Herein, the term “and/or” includes any and all combinations of one or more referents.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

As used herein the term “ohmic” refers to contacts where an impedance associated therewith is substantially given by the relationship of Impedance=V/I, where V is a voltage across the contact and I is the current, at substantially all expected operating frequencies (i.e., the impedance associated with the ohmic contact is substantially the same at all operating frequencies). For example, in some embodiments according to the invention, an ohmic contact can be a contact with a specific contact resistivity of less than about 10-03 ohm-cm2 and, in some embodiments less than about 10-04 ohm-cm2. Thus, a contact that is rectifying or that has a high specific contact resistivity, for example, a specific contact resistivity of greater than about 10-03 ohm-cm2, is not an ohmic contact as that term is used herein. It will also be understood that the term “ohmic” includes contacts that are non-rectifying in nature. For example, in some embodiments according to the invention, a Schottky semiconductor region would not function as an ohmic contact.

In some embodiments according to the invention, a vertical channel power MOSFET can be configured in a split gate arrangement where side-by-side transistors with respective gate electrodes are coupled together to operate as a single device. A Schottky semiconductor region can be embedded in a groove in an active region between the respective gate electrodes so that the junction between the Schottky semiconductor region and a conductive layer (which can provide the source contact for the vertical channel power MOSFET) is located beneath source regions that are located on upper portions of opposing side walls of the groove. The Schottky semiconductor region and the conductive layer can form a Schottky diode that is coupled in parallel with the body diodes formed by junctions in the active region. Coupling the embedded Schottky diode in parallel with the body diodes can increase the switching speed of the vertical channel power MOSFET while also reducing the size of the device.

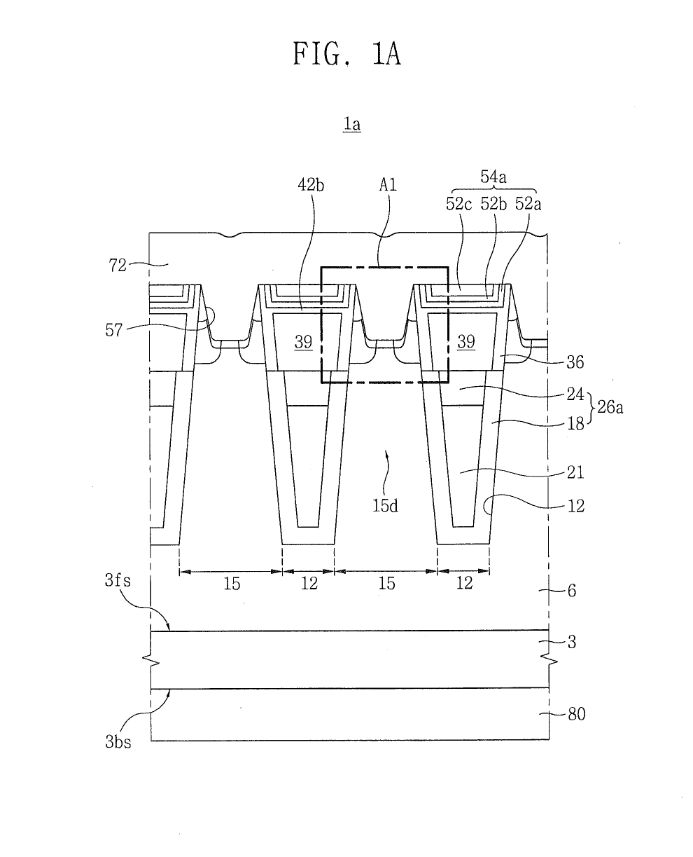

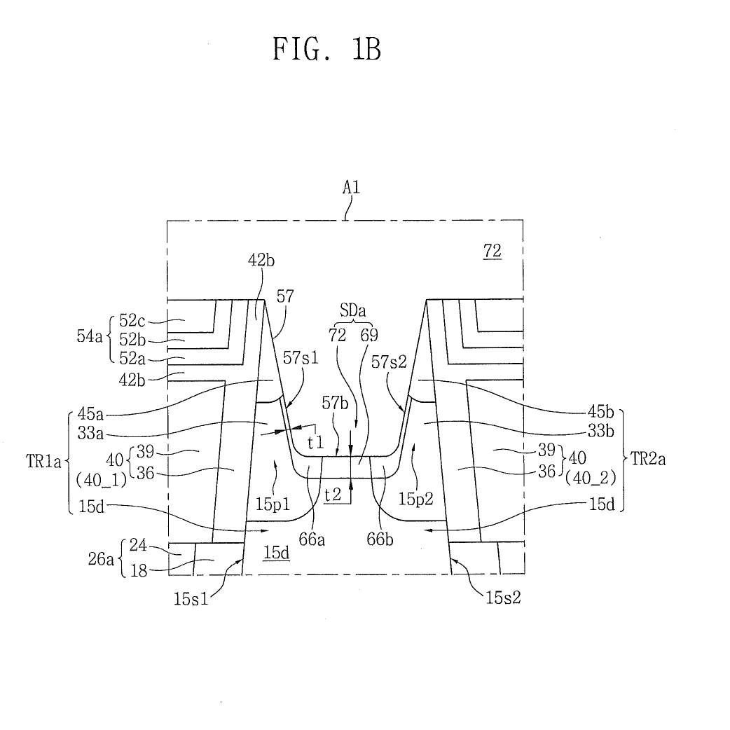

A semiconductor device 1a in accordance with an embodiment of the inventive concept will be described with reference to FIGS. 1A and 1B. FIG. 1A is a cross-sectional view showing the semiconductor device 1a in accordance with an embodiment of the inventive concept, and FIG. 1B is a partially enlarged view of the area marked A1 in FIG. 1A.

Referring to FIGS. 1A and 1B, the semiconductor device 1a in accordance with an embodiment of the inventive concept may include a semiconductor substrate 3 having a front side 3fs and a back side 3bs opposite to the front side 3fs. The semiconductor substrate 3 may have a first conductivity type. For example, the semiconductor substrate 3 may be a silicon substrate having N-type conductivity.

A semiconductor layer 6 may be disposed on the front side 3fs of the semiconductor substrate 3. The semiconductor layer 6 may be a single layer. The semiconductor layer 6 may be a single epitaxial layer formed in an epitaxial process.

The semiconductor layer 6 may be a single crystalline silicon layer. The semiconductor layer 6 may have the same conductivity type as the semiconductor substrate 3, but have a lower impurity concentration than the semiconductor substrate 3. For example, the semiconductor layer 6 may have the same N-type conductivity as the semiconductor substrate 3, but have a lower N-type impurity concentration than the semiconductor substrate 3.

A trench region 12 defining an active region 15 may be disposed in the semiconductor layer 6, The trench region 12 may have a tapered sidewall. For example, the trench region 12 may have a tapered sidewall, such that the trench region 12 gradually widens upwardly. Accordingly, the active region 15 defined by the trench region 12 may have tapered first and second side surfaces 15s1 and 15s2, such that the active region 15 gradually widens downwardly.

A shield conductive pattern 21, an insulating structure 26a, and a gate structure 40 may be disposed in the trench region 12.

The shield conductive pattern 21 may be formed to have a tapered side surface to gradually narrow downwardly. For example, the shield conductive pattern 21 may have an upper width greater than a lower width. The shield conductive pattern 21 may be formed of a conductive material such as polysilicon.

The insulating structure 26a may be disposed to surround the shield conductive pattern 21. The insulating structure 26a may include a first insulating pattern 18 and a second insulating pattern 24. The second insulating pattern 24 may be disposed to cover the shield conductive pattern 21. The first insulating pattern 18 may be disposed between the shield conductive pattern 21 and the sidewall of the trench region 12, and between the second insulating pattern 24 and the sidewall of the trench region 12. The first and second insulating patterns 18 and 24 may be formed of silicon oxide.

A gate structure 40 may be disposed on the insulating structure 26a. The gate structure 40 may include a gate dielectric layer 36 and a gate electrode 39. The gate electrode 39 may be disposed on the insulating structure 26a. The gate electrode 39 may be formed to have a greater width than a closest portion of the shield conductive pattern 21. The gate electrode 39 may have an upper width greater than a lower width. The gate electrode 39 may be formed of a conductive material such as polysilicon. The gate dielectric layer 36 may be disposed between the gate electrode 39 and the active region 15. The gate dielectric layer 36 may be formed of an insulating material such as silicon oxide. Meanwhile, the gate dielectric layer 36 may be formed to include a high dielectric material having a greater dielectric constant than silicon oxide. The gate dielectric layer 36 may be formed to have a smaller thickness than the first insulating pattern 18. Accordingly, a distance between the gate electrode 39 and the active region 15 may be smaller than a distance between the shield conductive pattern 21 and the active region 15.

An insulating capping pattern 54a may be disposed on the gate structure 40. The insulating capping pattern 54a may include a first insulating capping pattern 52a, a second insulating capping pattern 52b, and a third insulating capping pattern 52c. The first insulating capping pattern 52a may be formed of silicon oxide. The second insulating capping pattern 52b may be disposed on the first insulating capping pattern 52a. The third insulating capping pattern 52c may be formed on the second insulating capping pattern 52b. The second insulating capping pattern 52b may be formed of a different material from the first and third insulating capping patterns 52a and 52c. For example, the first and third insulating capping patterns 52a and 52c may be formed of silicon oxide, and the second insulating capping pattern 52b may be formed of silicon nitride. The third insulating capping pattern 52c may be formed to have a greater thickness than the second insulating capping pattern 52b.

An insulating buffer pattern 42b may be interposed between the insulating capping pattern 54a and the gate electrode 39, and between the insulating capping pattern 54a and the active region 15. The insulating buffer pattern 42b may be formed of silicon oxide. The insulating buffer pattern 42b may be formed to have a smaller thickness than the gate dielectric layer 36.

A groove region 57 may be disposed in an upper surface of the active region 15. The groove region 57 may have tapered first and second sidewalls 57s1 and 57s2, such that the groove region 57 gradually widens upwardly from a bottom surface 57b. The bottom surface 57b of the groove region 57 may be substantially flat.

The active region 15 may include first and second active protrusions 15p1 and 15p2 spaced apart from each other by the groove region 57. The first and second active protrusions 15p1 and 15p2 of the active region 15 may be defined between the groove region 57 and the trench region 12.

The first active protrusion 15p1 may be defined between the first sidewall 57s1 of the groove region 57 and the first side surface 15s1 of the active region 15. The first sidewall 57s1 of the groove region 57 and the first side surface 15s1 of the active region 15 may correspond to side surfaces of the first active protrusion 15p1. The first active protrusion 15p1 may have tapered side surfaces 57s1 and 15s1, and gradually widen downwardly.

The second active protrusion 15p2 may be defined between the second sidewall 57s2 of the groove region 57 and the second side surface 15s2 of the active region 15. The second sidewall 57s2 of the groove region 57 and the second side surface 15s2 of the active region 15 may correspond to side surfaces of the second active protrusion 15p2, The second active protrusion 15p2 may have tapered side surfaces 57s2 and 15s2, and gradually widen downwardly.

A front-side conductive pattern 72 may be disposed on the insulating capping pattern 54a and the active region 15. The front-side conductive pattern 72 may overlap the insulating capping pattern 54a and fill the groove region 57. The front-side conductive pattern 72 may be in contact with the active region 15 exposed by the groove region 57.

First and second source regions 45a and 45b spaced apart from each other may be disposed in the active region 15. The first source region 45a may be disposed in the first active protrusion 15p1 of the active region 15. The second source region 45b may be disposed in the second active protrusion 15p2 of the active region 15. The first and second source regions 45a and 45b may be spaced apart from each other.

The first and second source regions 45a and 45b may have bottom surfaces located at a higher level near the groove region 57 than near the trench region 12,

First and second body channel regions 33a and 33b spaced apart from each other may be disposed in the active region 15.

The first body channel region 33a may include a part formed in the first active protrusion 15p1 under the first source region 45a, and a part formed in the active region 15 under the first active protrusion 15p1. In the first body channel region 33a, the part formed in the active region 15 under the first active protrusion 15p1 may have a greater width than the part formed in the first active protrusion 15p1 under the first source region 45a.

The second body channel region 33b may include a part formed in the second active protrusion 15p2 under the second source region 45b, and a part formed in the active region 15 under the second active protrusion 15p2. In the second body channel region 33b, the part formed in the active region 15 under the second active protrusion 15p2 may have a greater width than the part formed in the second active protrusion 15p2 under the second source region 45b. The first and second body channel regions 33a and 33b may be spaced apart from each other,

The active region 15 located under the first and second body channel regions 33a and 33b may be defined as a drift region 15d.

First and second body contact regions 66a and 66b spaced apart from each other may be disposed in the active region 15. A Schottky semiconductor region 69 may be disposed in the active region 15 between the first and second body channel regions 33a and 33b, under the bottom surface 57b of the groove region 57. The Schottky semiconductor region 69 may be disposed in the active region 15 between the first and second body contact regions 66a and 66b, under the bottom surface 57b of the groove region 57.

The first body contact region 66a may be disposed in the active region 15 between the front-side conductive pattern 72 and the first body channel region 33a. The first body contact region 66a may be disposed in the first active protrusion 15p1 of the active region 15, and extend into the active region 15 under the first active protrusion 15p1. The first body contact region 66a may be formed to have a first depth t1 in the direction perpendicular to the first sidewall 57s1 of the groove region 57 from the first sidewall 57s1 of the groove region 57 near the first source region 45a, and a second depth t2 greater than the first depth t1 in the direction perpendicular to the bottom surface 57b of the groove region 57 from the bottom surface 57b of the groove region 57 near the Schottky semiconductor region 69.

The second body contact region 66b may be disposed in the active region 15 between the front-side conductive pattern 72 and the second body channel region 33b. The second body contact region 66b may be disposed in the second active protrusion 15p2 of the active region 15, and extend into the active region 15 under the second active protrusion 15p2. The second body contact region 66b may be formed to have the first depth t1 in the direction perpendicular to the second sidewall 57s2 of the groove region 57 from the second sidewall 57s2 of the groove region 57 near the second source region 45b, and the second depth t2 greater than the first depth t1 in the direction perpendicular to the bottom surface 57b of the groove region 57 from the bottom surface 57b of the groove region 57 near the Schottky semiconductor region 69,

The Schottky semiconductor region 69 may be disposed in the active region 15 located between the drift region 15d and the front-side conductive pattern 72, and between the first and second body contact regions 66a and 66b. The Schottky semiconductor region 69 may be disposed at a higher level than bottom surfaces of the first and second body channel regions 33a and 33b. The Schottky semiconductor region 69 may have a bottom surface in a constant depth from the bottom surface 57b of the groove region 57. The Schottky semiconductor region 69 may be formed to have a constant thickness.

The semiconductor layer 6 may be a single epitaxial layer, and the first and second body channel regions 33a and 33b, the drift region 15d, the Schottky semiconductor region 69, and the first and second source regions 45a and 45b may be disposed in the single epitaxial layer.

The semiconductor substrate 3, the semiconductor layer 6, the drift region 15d, the Schottky semiconductor region 69, and the first and second source regions 45a and 45b may have the first conductivity type. The first and second body channel regions 33a and 33b, and the first and second body contact regions 66a and 66b may have a second conductivity type different from the first conductivity type. For example, the semiconductor substrate 3, the semiconductor layer 6, the drift region 15d, the Schottky semiconductor region 69, and the first and second source regions 45a and 45b may have N-type conductivity, and the first and second body channel regions 33a and 33b, and the first and second body contact regions 66a and 66b may have P-type conductivity.

The Schottky semiconductor region 69 may have a lower majority carrier concentration than the drift region 15d in the semiconductor layer 6 adjacent to the Schottky semiconductor region 69. The Schottky semiconductor region 69 may have a lower impurity concentration to form an N-type semiconductor than the drift region 15d in the semiconductor layer 6 adjacent to the Schottky semiconductor region 69. For example, the Schottky semiconductor region 69 may be an N-type conductivity region which is formed by injecting a 13th group element of the long-form Periodic Table, for example, boron, into the semiconductor layer 6 having N-type conductivity to reduce the majority carrier concentration of the semiconductor layer 6.

Since the semiconductor layer 6 is formed of a single epitaxial layer including a 15th group element of the long-form Periodic Table, such as P and As, the Schottky semiconductor region 69 formed by injecting the 13th group element of the long-form Periodic Table into the semiconductor layer 6, may include both of the 13th group element and the 15th group element. In addition, the amount per unit volume of 15th group element may be greater than the amount per unit volume of 13th group element in the Schottky semiconductor region 69, and the drift region 15d in the semiconductor layer 6 adjacent to the Schottky semiconductor region 69 may have the same amount per unit volume of 15th group element as the Schottky semiconductor region 69. Further, the drift region 15d in the semiconductor layer 6 adjacent to the Schottky semiconductor region 69 may have a higher majority carrier concentration than the Schottky semiconductor region 69.

The first and second body channel regions 33a and 33b may include both of the 13th group element and the 15th group element of the long-form Periodic Table, and have P-type conductivity. The amount per unit volume of 15th group element in the first and second body channel regions 33a and 33b, may be less than the amount per unit volume of 13th group element in the Schottky semiconductor region 69. Since the first and second body channel regions 33a and 33b are formed by ion-implantation of a 13th group element into the semiconductor layer 6 formed of a single epitaxial layer, the first and second body channel regions 33a and 33b may have the same amount per unit volume of 15th group element as the semiconductor layer 6,

The first and second body contact regions 66a and 66b may have a higher majority carrier concentration than the first and second body channel regions 33a and 33b adjacent to the first and second body contact regions 66a and 66b. For example, the first and second body contact regions 66a and 66b may have a higher impurity concentration than the first and second body channel regions 33a and 33b adjacent to the first and second body contact regions 66a and 66b, to form a P-type semiconductor.

The first and second body contact regions 66a and 66b may include a 13th group element and a 15th group element of the long-form Periodic Table, and have P-type conductivity. In addition, the first and second body contact regions 66a and 66b may the same amount per unit volume of 15th group element as the first and second body channel regions 33a and 33b, and a greater amount per unit volume of 15th group element than the first and second body channel regions 33a and 33b.

The first and second source regions 45a and 45b may have a higher majority carrier concentration than the drift region 15d of the semiconductor layer 6. For example, the first and second source regions 45a and 45b may have a greater amount per unit volume of 15th group element of the long-form Periodic Table than the drift region 15d of the semiconductor layer 6.

The first and second source regions 45a and 45b may form ohmic contacts with the front-side conductive pattern 72. The first and second body contact regions 66a and 66b may form ohmic contacts with the front-side conductive pattern 72.

Since bottom surfaces of the first and second source regions 45a and 45b are located at a higher level near the groove region 57 than near the trench region 12, resistance properties between the first and second body contact regions 66a and 66b and the front-side conductive pattern 72 may be improved. Accordingly, body contact resistance of the semiconductor device 1a may be reduced. For example, since the bottom surfaces of the first and second source regions 45a and 45b are located at a higher level near the groove region 57 than near the trench region 12, a distance between the Schottky semiconductor region 69 and the first and second source regions 45a and 45b may increase, and thereby areas of the first and second body contact regions 66a and 66b disposed between the Schottky semiconductor region 69 and the first and second source regions 45a and 45b may increase. Accordingly, a contact region between the front-side conductive pattern 72 and the first and second body contact regions 66a and 66b may increase, and thereby resistance properties between the first and second body contact regions 66a and 66b and the front-side conductive pattern 72 may be improved.

A back-side conductive layer 80 may be disposed on the back side 3bs of the semiconductor substrate 3. The back-side conductive layer 80 may form an ohmic contact with the back side 3bs of the semiconductor substrate 3. The back-side conductive layer 80 may be electrically connected to the drift region 15d via the semiconductor substrate 3 and the semiconductor layer 6.

The Schottky semiconductor region 69 may have N-type conductivity and form a Schottky diode SDa with the front-side conductive pattern 72. The P-type first and second body channel regions 33a and 33b and the N-type drift region 15d may form a PN diode,

The first source region 45a, the first body channel region 33a, the drift region 15d, and the gate structure 40 adjacent to the first body channel region 33a may be configured as a first transistor TR1a. Here, the gate structure 40 adjacent to the first body channel region 33a may be defined as a first gate structure 40_1, The second source region 45b, the second body channel region 33b, the drift region 15d, and the gate structure 40 adjacent to the second body channel region 33b may be configured as a second transistor TR2a. Here, the gate structure 40 adjacent to the second body channel region 33b may be defined as a second gate structure 40_2.

The first and second transistors TR1a and TR2a may share the drift region 15d. In addition, the first and second source regions 45a and 45b may be electrically connected by the front-side conductive pattern 72. Accordingly, the first and second transistors TR1a and TR2a may operate as a single transistor by controlling the first and second gate structures 40_1 and 40_2 together. For example, in order to simultaneously turn on the first and second transistors TR1a and TR2a, a voltage may be simultaneously applied to the gate electrodes 39 of the first and second gate structures 40_1 and 40_2. Accordingly, the gate structure 40, the drift region 15d, the first and second body channel regions 33a and 33b, and the first and second source regions 45a and 45b may be configured as a single transistor.

The SDa 69 is embedded between the first and second transistors TR1a and TR2a. Further, the first and second gate electrodes 39 can be configured together to provide a split-gate for the combination of the first and second transistors TR1a and TR2a as a single split-gate power MOSFET in some embodiments according to the invention. Accordingly, a vertical channel power MOSFET device can include both a split gate arrangement and an embedded Schottky diode.

As appreciated by the present inventors, since the Schottky diode has a lower _{VSD} value than the body diode, dead time and power loss may be reduced.

The back-side conductive layer 80 may function as a drain terminal of the first and second transistors TR1a and TR2a, and the front-side conductive pattern 72 may function as a source terminal of the first and second transistors TR1a and TR2a.

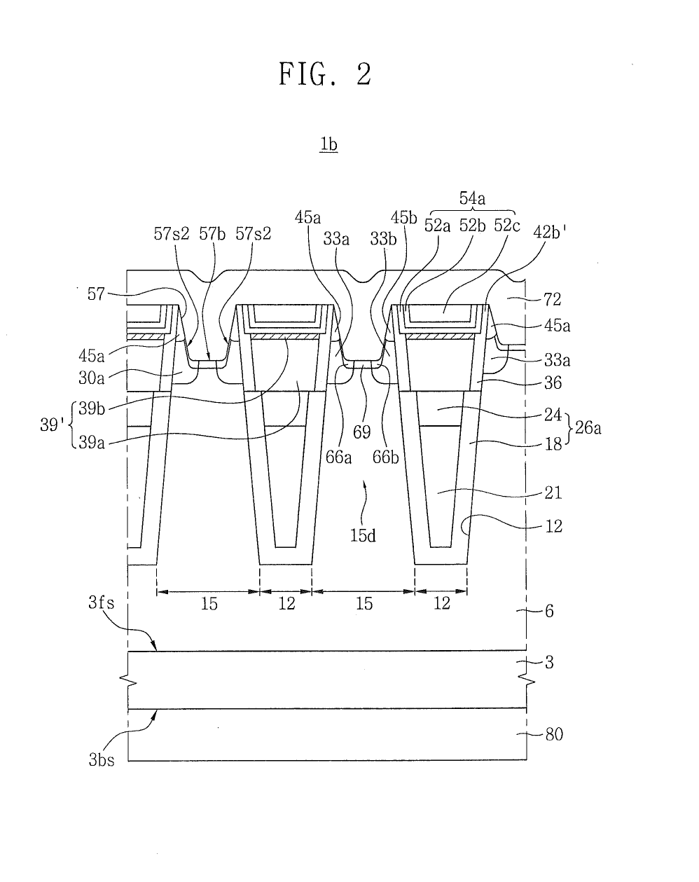

The gate electrode 39 may be formed of a polysilicon single layer. However, the inventive concept is not limited thereto. For example, the gate electrode 39 in FIGS. 1A and 1B, may be modified to a gate electrode 39′ which includes a polysilicon pattern 39a and a metal-semiconductor compound layer 39b disposed on the polysilicon pattern 39a, as shown in FIG. 2. The metal-semiconductor compound layer 39b may be formed of a silicide, such as CoSi, NiSi, or WSi, and the metal-semiconductor compound layer 39b may improve the electrical properties of the modified gate electrode 39′. Accordingly, the modified gate electrode 39′ having improved electrical properties may improve the performance of a semiconductor device 1b.

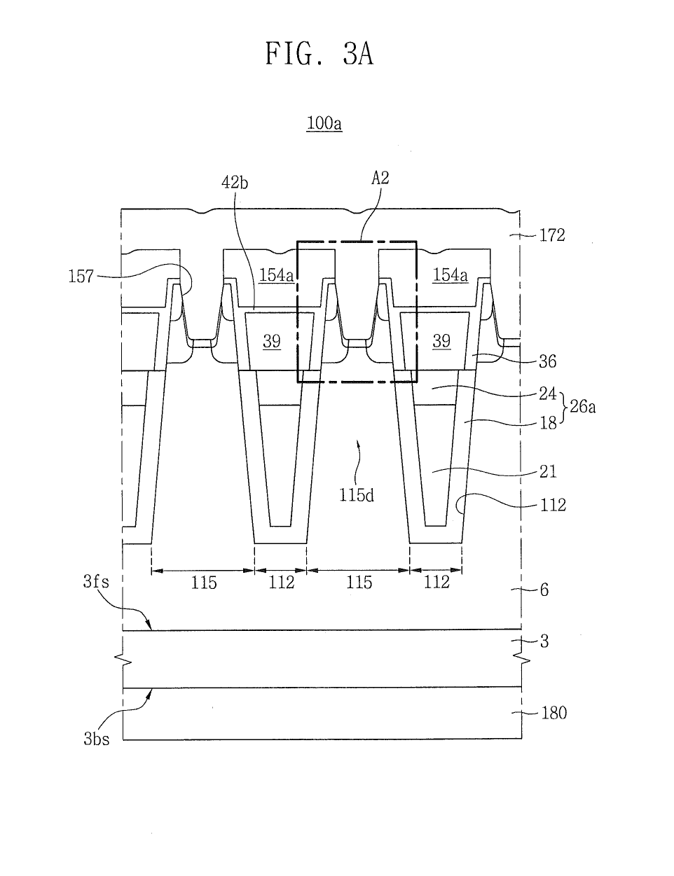

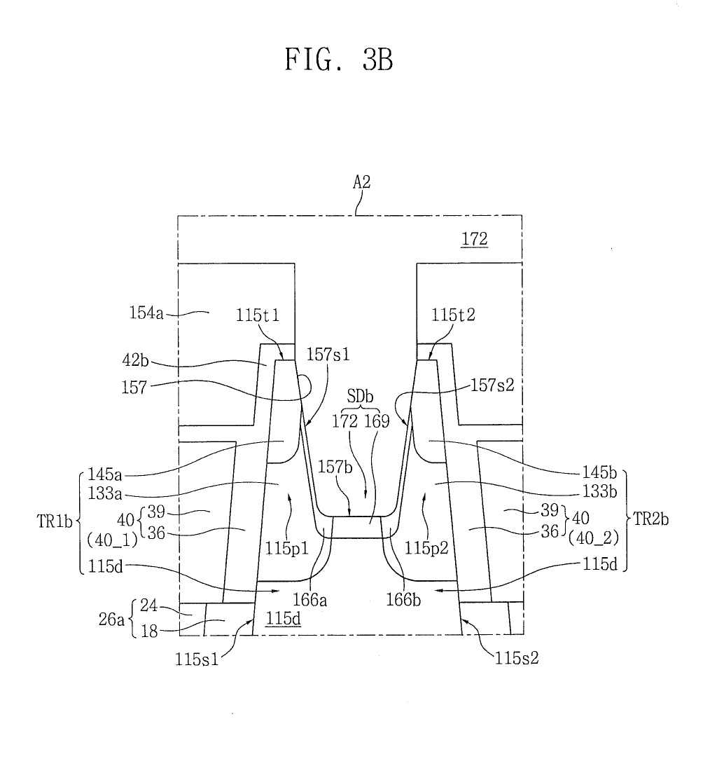

A semiconductor device 100a in accordance with another embodiment of the inventive concept is described with reference to FIGS. 3A and 3B. FIG. 3A is a cross-sectional view schematically showing the semiconductor device 100a in accordance with another embodiment of the inventive concept, and FIG. 3B is a partially enlarged view showing the part marked A2 in FIG. 3A.

Referring to FIGS. 3A and 3B, the semiconductor device 100a in accordance with another embodiment of the inventive concept may include the semiconductor substrate 3 having the front side 3fs and the back side 3bs, and the semiconductor layer 6 disposed on the front side 3fs of the semiconductor substrate 3 as described with reference to FIGS. 1A and 1B. The semiconductor layer 6 may be a single epitaxial layer.

A trench region 112 defining an active region 115 may be disposed in the semiconductor layer 6.

The shield conductive pattern 21, the insulating structure 26a surrounding the shield conductive pattern 21, and the gate structure 40 disposed on the insulating structure 26a, as described with reference to FIGS. 1A and 1B, may be disposed in the trench region 112.

The active region 115 may have tapered sidewalls 115s1 and 115s2 to narrow upwardly. The active region 115 may include first and second active protrusions 115p1 and 115p2 spaced apart from each other by a groove region 157 formed in an upper surface of the active region 115. The groove region 157 may have tapered first and second sidewalls 157s1 and 157s2, such that the groove region 157 gradually widens upwardly from a bottom surface 157b. In addition, an upper edge of the groove region 157 may be spaced apart from the trench region 112. The first and second active protrusions 115p1 and 115p2 of the active region 115 may be defined between the groove region 157 and the trench region 112.

The first active protrusion 115p1 may be defined between the first sidewall 157s1 of the groove region 157 and the first side surface 115s1 of the active region 115. The first sidewall 157s1 of the groove region 157 and the first side surface 115s1 of the active region 115 may correspond to side surfaces of the first active protrusion 115p1, The first active protrusion 115p1 may have tapered side surfaces 157s1 and 115s1, and gradually widen downwardly from a top surface 115t1.

The second active protrusion 115p2 may be defined between the second sidewall 157s2 of the groove region 157 and the second side surface 115s2 of the active region 115. The second sidewall 157s2 of the groove region 157 and the second side surface 115s2 of the active region 115 may correspond to side surfaces of the second active protrusion 115p2, The second active protrusion 115p2 may have tapered side surfaces 157s1 and 115s1, and gradually widen downwardly from a top surface 115t2.

Insulating capping patterns 154a may be disposed on a part of the active region 115 and on the gate structure 40. The insulating capping patterns 154a may overlap the gate structure 40, and vertically overlap part of the active region 115. The insulating capping patterns 154a may overlap the gate structure 40, the top surface 115t1 of the first active protrusion 115p1, and the top surface 115t2 of the second active protrusion 115p2. The insulating capping patterns 154a may be formed of an insulating material such as silicon oxide.

An insulating buffer pattern 42b may be interposed between the insulating capping patterns 154a and the gate electrode 39, and between the insulating capping patterns 154a and the active region 115. The insulating buffer pattern 42b may be formed to have a smaller thickness than the gate dielectric layer 36. The insulating buffer pattern 42b may be formed of an insulating material such as silicon oxide.

A front-side conductive pattern 172 may be formed on the insulating capping patterns 154a and the active region 115. The front-side conductive pattern 172 may overlap the insulating capping patterns 154a and be in contact with the active region 115 exposed by the groove region 157. The front-side conductive pattern 172 may fill the groove region 157.

First and second source regions 145a and 145b may be disposed in the active region 115. The first source region 145a may be disposed in the first active protrusion 115p1 of the active region 115, The second source region 145b may be disposed in the second active protrusion 115p2 of the active region 115. Bottom surfaces of the first and second source regions 145a and 145b may be located at a higher level near the groove region 157 than near the trench region 112. The first and second source regions 145a and 145b having the bottom surfaces may improve body contact resistance of the semiconductor device 100a, for the same reason as the first and second source regions 45a and 45b described in FIGS. 1A and 1B.

First and second body channel regions 133a and 133b may be disposed in the active region 115. The first and second body channel regions 133a and 133b may correspond to the first and second body channel regions 33a and 33b described in FIGS. 1A and 1B. The first body channel region 133a may include a part formed in the first active protrusion 115p1 under the first source region 145a, and a part formed in the active region 115 under the first active protrusion 115p1. The second body channel region 133b may include a part formed in the second active protrusion 115p2 under the second source region 145b, and a part formed in the active region 115 under the second active protrusion 115p2.

The active region 115 disposed under the first and second body channel regions 133a and 133b may be defined as a drift region 115d.

First and second body contact regions 166a and 166b, and a Schottky semiconductor region 169 may be disposed in the active region 115. The first body contact region 166a may be disposed in the active region 115 between the front-side conductive pattern 172 and the first body channel region 133a. The first body contact region 166a may be disposed in the first active protrusion 115p 1 of the active region 115, and extend into the active region 115 under the first active protrusion 115p1. The first body contact region 166a may be formed to have a first depth in the direction perpendicular to the first sidewall 157s1 of the groove region 157 from the first sidewall 157s1 of the groove region 157 near the first source region 145a, and a second depth, greater than the first depth, in the direction perpendicular to the bottom surface 157b of the groove region 157 from the bottom surface 157b of the groove region 157 near the Schottky semiconductor region 169. The second body contact region 166b may be disposed in the active region 115 between the front-side conductive pattern 172 and the second body channel region 133b. The second body contact region 166b may be disposed in the second active protrusion 115p2 of the active region 115, and extend into the active region 115 under the second active protrusion 115p2. The second body contact region 166b may be formed to have the first depth in the direction perpendicular to the second sidewall 157s2 of the groove region 157 from the second sidewall 157s2 of the groove region 157 near the second source region 145b, and the second depth greater than the first depth in the direction perpendicular to the bottom surface 157b of the groove region 157 from the bottom surface 157b of the groove region 157 near the Schottky semiconductor region 169.

The Schottky semiconductor region 169 may be disposed in the active region 115 located between the first and second active protrusions 115p1 and 115p2. The Schottky semiconductor region 169 may be formed in a constant depth from the bottom surface 157b of the groove region 157, The Schottky semiconductor region 169 may be disposed in the active region 115 between the drift region 115d and the front-side conductive pattern 172, and between the first and second body contact regions 166a and 166b. The Schottky semiconductor region 169 may be disposed at a higher level than bottom surfaces of the first and second body channel regions 133a and 133b.

The SDb 169 is embedded between the first and second transistors TR1b and TR2b. Further, the first and second gate electrodes 39 can be configured together to provide a split-gate for the combination of the first and second transistors TR1b and TR2b as a single split-gate power MOSFET in some embodiments according to the invention. Accordingly, a vertical channel power MOSFET device can include both a split gate arrangement and an embedded Schottky diode.

As appreciated by the present inventors, since the Schottky diode has a lower _{VSD} value than the body diode, dead time and power loss may be reduced.

According to some embodiments of the inventive concept, a power MOSFET device can include both a split gate arrangement and an embedded Schottky diode.

The drift region 115d, the Schottky semiconductor region 169, and the first and second source regions 145a and 145b may have N-type conductivity, and the first and second body channel regions 133a and 133b, and the first and second body contact regions 166a and 166b may have P-type conductivity.

The drift region 115d, the Schottky semiconductor region 169, and the first and second source regions 145a and 145b may respectively correspond to the drift region 15d, the Schottky semiconductor region 69, and the first and second source regions 45a and 45b described in FIGS. 1A and 1B. For example, the Schottky semiconductor region 169, as the Schottky semiconductor region 69 described in FIGS. 1A and 1B, may include both 13th group element and 15th group element of the long-form Periodic Table. In the Schottky semiconductor region 169, the amount per unit volume of 15th group element may be greater than the amount per unit volume of 13th group element. In addition, the Schottky semiconductor region 169 may have the same amount per unit volume of 15th group element as the drift region 115d in the semiconductor layer 6 adjacent to the Schottky semiconductor region 169. Further, the Schottky semiconductor region 169 may have a lower majority carrier concentration than the drift region 115d in the semiconductor layer 6 adjacent to the Schottky semiconductor region 169.

The first and second body channel regions 133a and 133b, and the first and second body contact regions 166a and 166b may respectively correspond to the first and second body channel regions 33a and 33b, and the first and second body contact regions 66a and 66b described in FIGS. 1A and 1B. For example, the first and second body contact regions 166a and 166b may have a greater impurity concentration to form a P-type semiconductor than the first and second body channel regions 133a and 133b adjacent to the first and second body contact regions 166a and 166b.

The first and second source regions 145a and 145b may have a greater majority carrier concentration than the drift region 115d of the semiconductor layer 6. For example, the first and second source regions 145a and 145b may have a greater amount per unit volume of 15th group element of the long-form Periodic Table than the drift region 115d of the semiconductor layer 6.

The first and second source regions 145a and 145b may form ohmic contacts with the front-side conductive pattern 172. The first and second body contact regions 166a and 166b may form ohmic contacts with the front-side conductive pattern 172.

A back-side conductive layer 180 may be disposed on the back side 3bs of the semiconductor substrate 3. The back-side conductive layer 180 may form an ohmic contact with the back side 3bs of the semiconductor substrate 3. The back-side conductive layer 180 may be electrically connected to the drift region 115d via the semiconductor substrate 3 and the semiconductor layer 6.

The first and second source regions 145a and 145b may form ohmic contacts with the front-side conductive pattern 172. The first and second body contact regions 166a and 166b may form ohmic contacts with the front-side conductive pattern 172. The Schottky semiconductor region 169 may have N-type conductivity, and form a Schottky diode SDb with the front-side conductive pattern 172.

The first source region 145a, the first body channel region 133a, the drift region 115d, and the first gate structure 40_1 may be configured as a first transistor TR1b. The second source region 145b, the second body channel region 133b, the drift region 115d, and the second gate structure 40_2 may be configured as a second transistor TR2b. The first and second transistors TR1b and TR2b may share the drift region 115d. Accordingly, the first and second transistors TR1b and TR2b may operate as a single transistor by controlling the first and second gate structures 40_1 and 40_2 together.

The back-side conductive layer 180 may function as a drain terminal of the first and second transistors TR1b and TR2b, and the front-side conductive pattern 172 may function as a source terminal of the first and second transistors TR1b and TR2b.

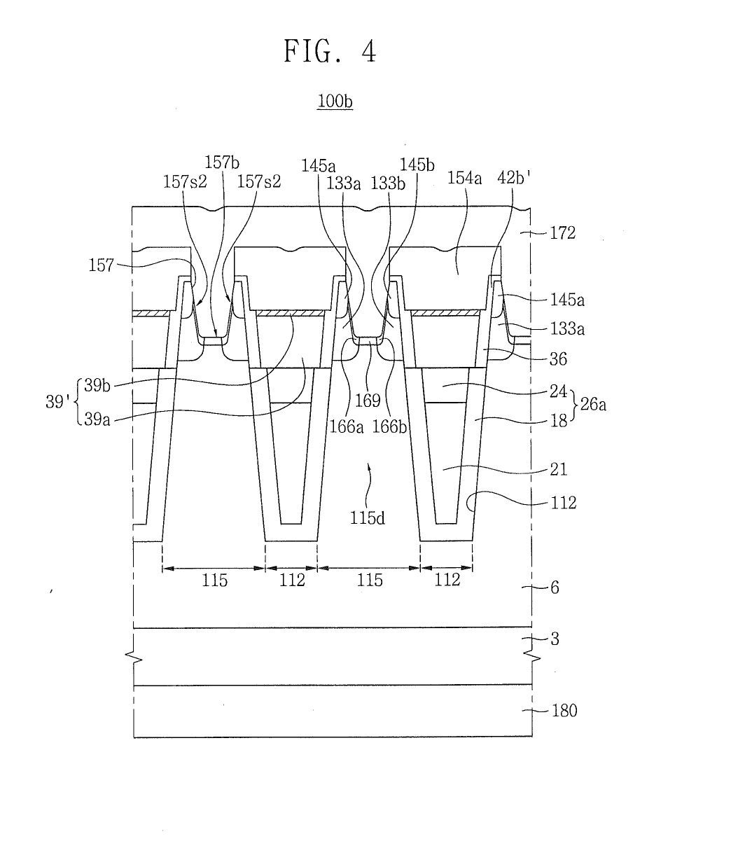

The semiconductor device 100a may include the gate electrode 39 formed of a polysilicon single layer. However, the inventive concept is not limited thereto. For example, the gate electrode 39 may be modified to a gate electrode 39′ which includes a polysilicon pattern 39a and a metal-semiconductor compound layer 39b disposed on the polysilicon pattern 39a, as shown in FIG. 4. The metal-semiconductor compound layer 39b may be formed of a silicide, such as CoSi, NiSi, or WSi. Accordingly, a semiconductor device 100b including the modified gate electrode 39′ having improved electrical properties may be provided.

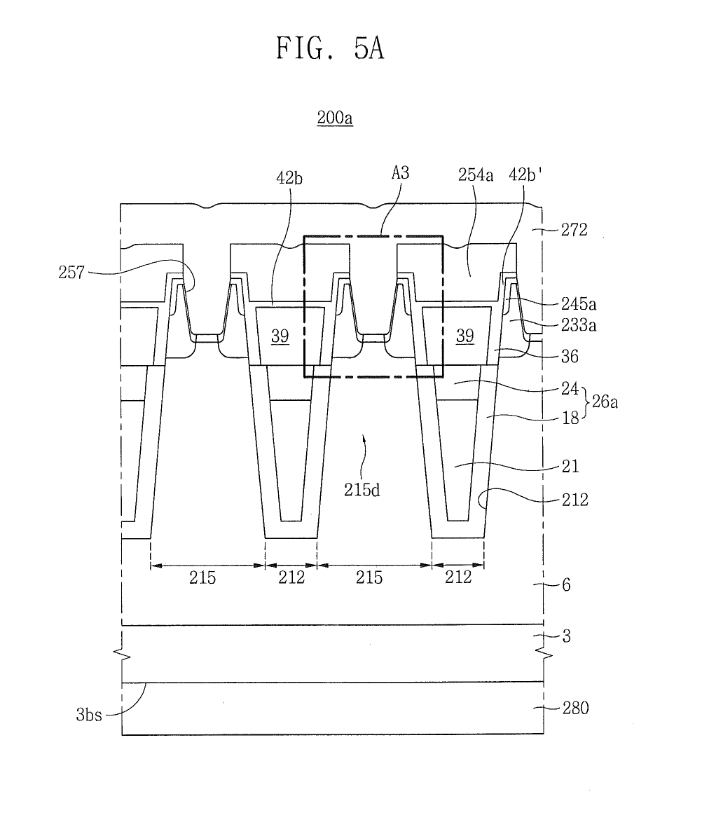

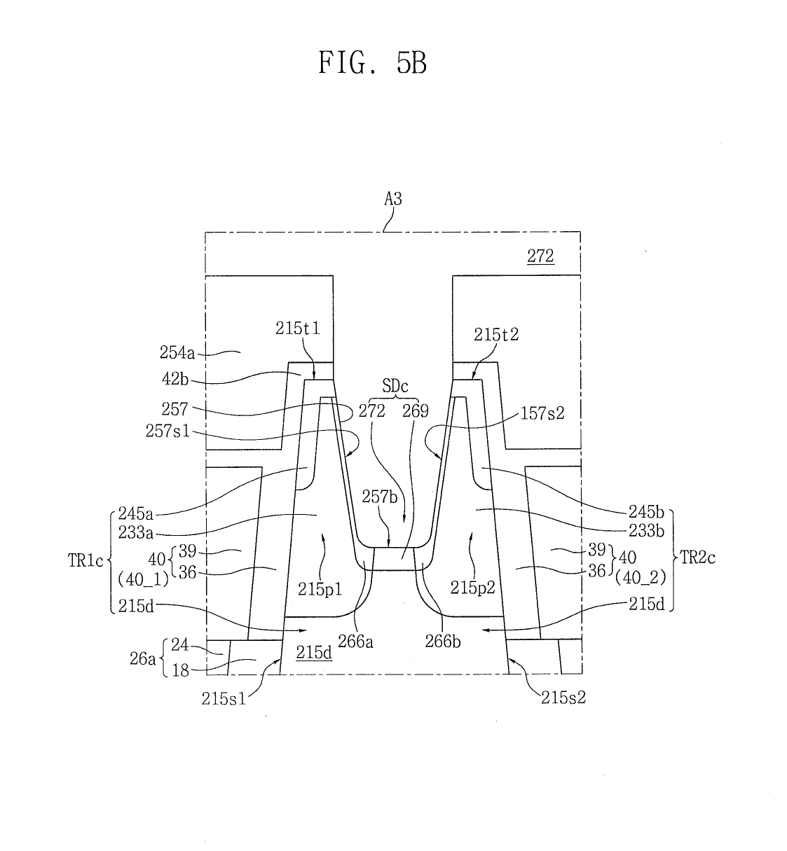

A semiconductor device 200a in accordance with still another embodiment of the inventive concept will be described with reference to FIGS. 5A and 5B. FIG. 5A is a cross-sectional view schematically showing the semiconductor device 200a in accordance with still another embodiment of the inventive concept, and FIG. 5B is a partially enlarged view showing the part marked A3 in FIG. 5A,

Referring to FIGS. 5A and 5B, the semiconductor device 200a in accordance with still another embodiment of the inventive concept may be provided. The semiconductor device 200a may include the semiconductor substrate 3, and the semiconductor layer 6 disposed on the front side 3fs of the semiconductor substrate 3 as described with reference to FIGS. 3A and 3B.

A trench region 212 defining an active region 215 may be disposed in the semiconductor layer 6. The active region 215 may have tapered side surfaces 215s1 and 215s2 to narrow upwardly. The active region 215 may include first and second active protrusions 215p1 and 215p2. The first and second active protrusions 215p1 and 215p2 of the active region 215 may be spaced apart from each other by a groove region 257 formed at in an upper surface of the active region 215. The first and second active protrusions 215p1 and 215p2 of the active region 215 may be defined between the groove region 257 and the trench region 212, Each of the first and second active protrusions 215p1 and 215p2 may have tapered side surfaces to gradually narrow upwardly. In addition, each of the first and second active protrusions 215p1 and 215p2 may have upper surfaces 215t1 and 215t2.

The shield conductive pattern 21, the insulating structure 26a surrounding the shield conductive pattern 21, and the gate structure 40 disposed on the insulating structure 26a, as described in FIGS. 3A and 3B, may be disposed in the trench region 212.

An insulating capping pattern 254a may overlap the gate structure 40 and the upper surfaces 215t1 and 215t2 of the first and second active protrusions 215p1 and 215p2 of the active region 215. The insulating capping pattern 254a may be formed of silicon oxide using a deposition process.

The insulating buffer pattern 42b may be interposed between the gate electrode 39 and the insulating capping pattern 254a, and between the insulating capping pattern 254a and the active region 215. The insulating buffer pattern 42b may have a smaller thickness than the gate dielectric layer 36, but be formed of the same layer as the gate dielectric layer 36, for example, a thermal oxide.

A front-side conductive pattern 272 may be disposed on the insulating capping pattern 254a and the active region 215. The front-side conductive pattern 272 may overlap the insulating capping pattern 254a, and be in contact with the active region 215 exposed by the groove region 257. The front-side conductive pattern 272 may fill the groove region 257.

First and second source regions 245a and 245b, and first and second body channel regions 233a and 233b may be disposed in the active region 215. In addition, first and second body contact regions 266a and 266b, and a Schottky semiconductor region 269 may be disposed in the active region 215.

The first source region 245a may be formed in the first active protrusion 215p1 of the active region 215. The second source region 245b may be formed in the second active protrusion 215p2 of the active region 215. In the first source region 245a, a bottom surface near the first side surface 215s1 of the active region 215 may be formed at a higher level than a bottom surface near the first sidewall 257s1 of the groove region 257. For example, the first source region 245a may be formed to have a first junction depth from the upper surface 215t1 of the first active protrusion 215p1 near the first side surface 215s1 of the active region 215, and a second junction depth, smaller than the first junction depth, from the upper surface 215t1 of the first active protrusion 215p1 near the first sidewall 257s1 of the groove region 257.

In addition, the bottom surface of the first source region 245a may have a steep slope between the first side surface 215s1 of the active region 215 and the first sidewall 257s1 of the groove region 257, and a slight slope or evenness near the first sidewall 257s1 of the groove region 257. In the first source region 245a, the bottom surface of the first source region 245a located between the first side surface 215s1 of the active region 215 and the first sidewall 257s1 of the groove region 257 may have substantially the same slope as the tapered first side surface 215s1 of the active region 215, For example, in the first source region 245a, the bottom surface of the first source region 245a located between the first side surface 215s1 of the active region 215 and the first sidewall 257s1 of the groove region 257 may be substantially parallel to the tapered first side surface 215s1 of the active region 215,

The second source region 245b and the first source region 245a may have a symmetrical structure with respect to the groove region 257. Accordingly, a bottom surface of the second source region 245b may be formed at a higher level near the second side surface 215s2 of the active region 215 than near the second sidewall 257s2 of the groove region 257. In addition, the bottom surface of the second source region 245b may have a steep slope between the second side surface 215s2 of the active region 215 and the second sidewall 257s2 of the groove region 257, and a slight slope or evenness near the second sidewall 257s2 of the groove region 257. In the second source region 245b, the bottom surface of the second source region 245b located between the second side surface 215s2 of the active region 215 and the second sidewall 257s2 of the groove region 257 may have substantially the same slope as the tapered second side surface 215s2 of the active region 215.

The first and second source regions 245a and 245b may improve body contact resistance of the semiconductor device 200a, for the same reason as the first and second source regions 45a and 45b described in FIGS. 1A and 1B.

The first body channel region 233a may include a part formed in the first active protrusion 215p1 under the first source region 245a, and a part formed in the active region 215 under the first active protrusion 215p1.

The second body channel region 233b may include a part formed in the second active protrusion 215p2 under the second source region 245b, and a part formed in the active region 215 under the second active protrusion 215p2.

The first body contact region 266a, like the first body contact region 166a described in FIGS. 3A and 3B, may be disposed in the active region 215 between the front-side conductive pattern 272 and the first body channel region 233a.

The second body contact region 266b, like the second body contact region 166b described in FIGS. 3A and 3B, may be disposed in the active region 215 between the front-side conductive pattern 272 and the second body channel region 233b.

The active region 215 under the first and second body channel regions 233a and 233b may be defined as a drift region 215d.

The drift region 215d, the Schottky semiconductor region 269, and the first and second source regions 245a and 245b may respectively correspond to the drift region 15d, the Schottky semiconductor region 69, and the first and second source regions 45a and 45b described in FIGS. 1A and 1B. For example, the Schottky semiconductor region 269 may have a lower impurity concentration to form an N-type semiconductor than the drift region 215d in the semiconductor layer 6 adjacent to the Schottky semiconductor region 269.

The first and second body channel regions 233a and 233b, and the first and second body contact regions 266a and 266b may respectively correspond to the first and second body channel regions 33a and 33b, and the first and second body contact regions 66a and 66b described in FIGS. 1A and 1B. For example, the first and second body contact regions 266a and 266b may have a higher impurity concentration to form a P-type semiconductor than the first and second body channel regions 233a and 233b adjacent to the first and second body contact regions 266a and 266b.

A back-side conductive layer 280 may be disposed on the back side 3bs of the semiconductor substrate 3. The back-side conductive layer 280 may form an ohmic contact with the back side 3bs of the semiconductor substrate 3.

The first and second source regions 245a and 245b may form an ohmic contact with the front-side conductive pattern 272. The first and second body contact regions 266a and 266b may form ohmic contacts with the front-side conductive pattern 272. The Schottky semiconductor region 269 may have N-type conductivity, and form a Schottky diode SDc with the front-side conductive pattern 272.

The first source region 245a, the first body channel region 233a, the drift region 215d, and the first gate structure 40_1 may be configured as a first transistor TR1c. The second source region 245b, the second body channel region 233b, the drift region 215d, and the second gate structure 40_2 may be configured as a second transistor TR2c. The first and second transistors TR1c and TR2c may share the drift region 215d. Accordingly, the first and second gate structures 40_1 and 40_2 may be controlled together, and thereby the first and second transistors TR1c and TR2c may operate like a single transistor.

The Schottky semiconductor region 269 is embedded between the first and second transistors TR1c and TR2c. Further, the first and second gate electrodes 39 can be configured together to provide a split-gate for the combination of the first and second transistors TR1c and TR2c outputs a single split-gate power MOSFET in some embodiments according to the invention. As appreciated by the present inventors, since the Schottky diode has a lower _{VSD} value than the body diode, dead time and power loss may be reduced.

According to some embodiments of the inventive concept, a power MOSFET device can include both a split gate arrangement and an embedded Schottky diode.

The back-side conductive layer 280 may function as a drain terminal of the first and second transistors TR1c and TR2c, and the front-side conductive pattern 272 may function as a source terminal of the first and second transistors TR1c and TR2c.

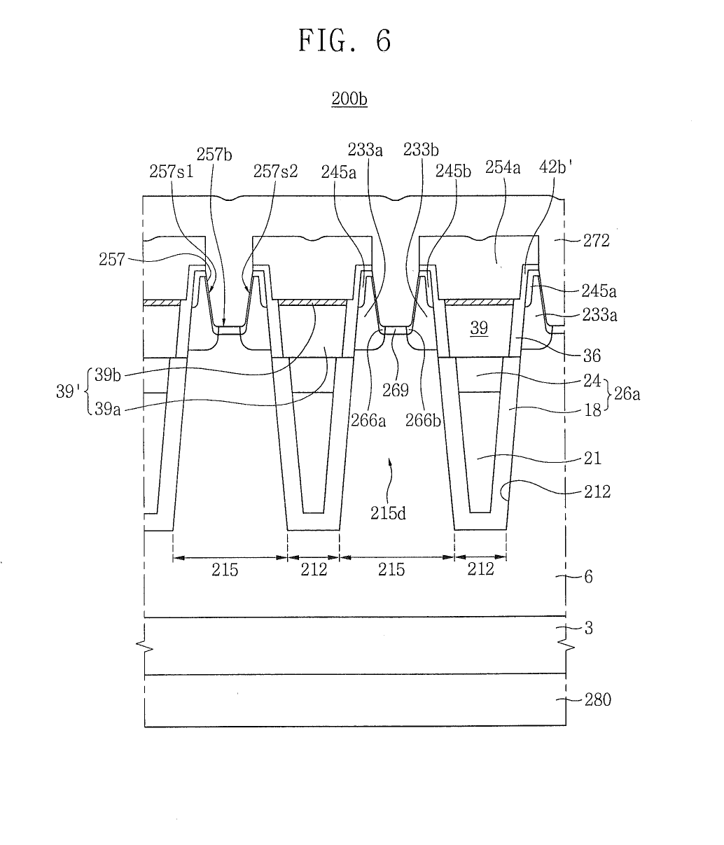

The semiconductor device 200a may include the gate electrode 39 formed of a polysilicon single layer. However, the inventive concept is not limited thereto. For example, the gate electrode 39 may be modified to a gate electrode 39′ which includes a polysilicon pattern 39a and a metal-semiconductor compound layer 39b disposed on the polysilicon pattern 39a, as shown in FIG. 6. The metal-semiconductor compound layer 39b may be formed of a silicide, such as CoSi, NiSi, and WSi. Accordingly, a semiconductor device 200b including the modified gate electrode 39′ having improved electrical properties may be provided.

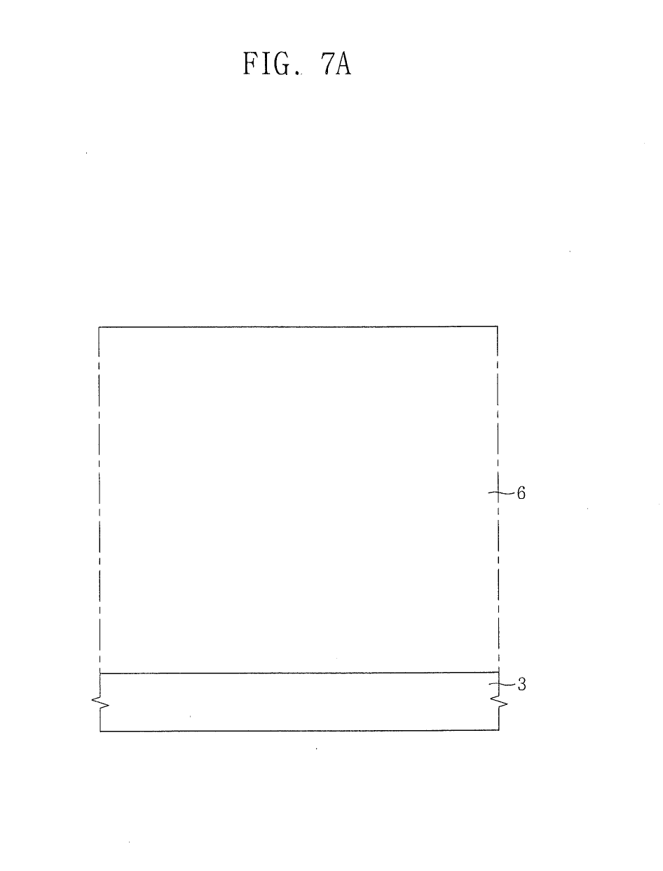

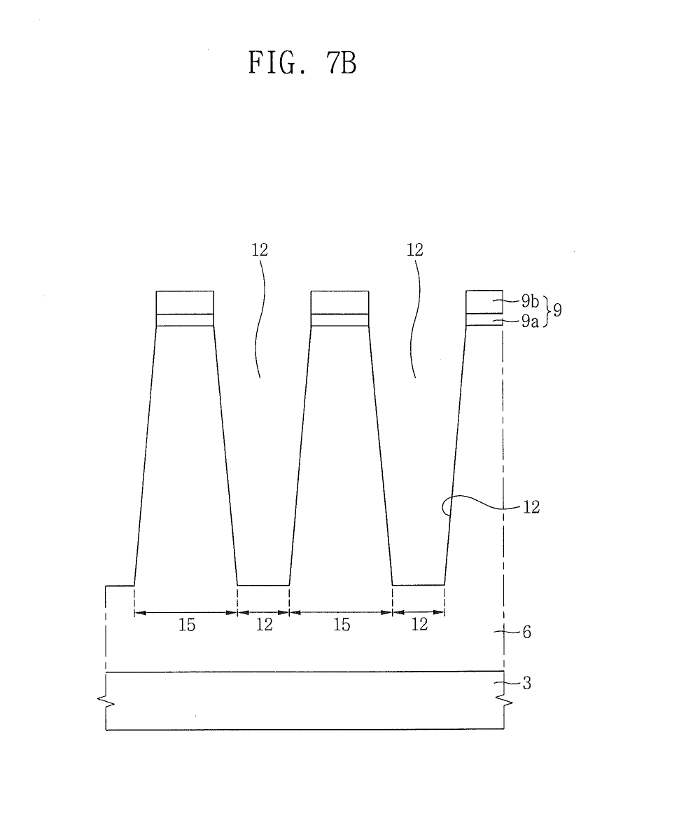

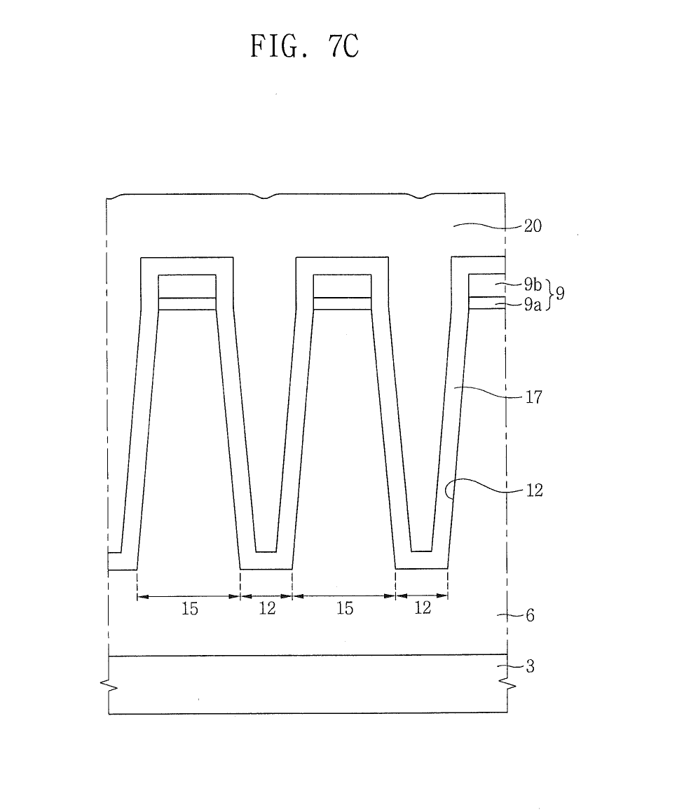

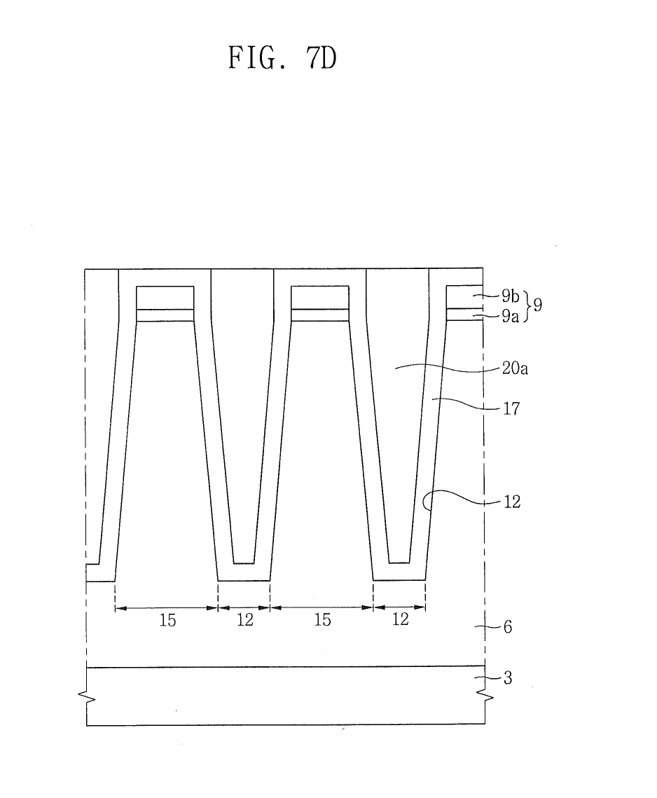

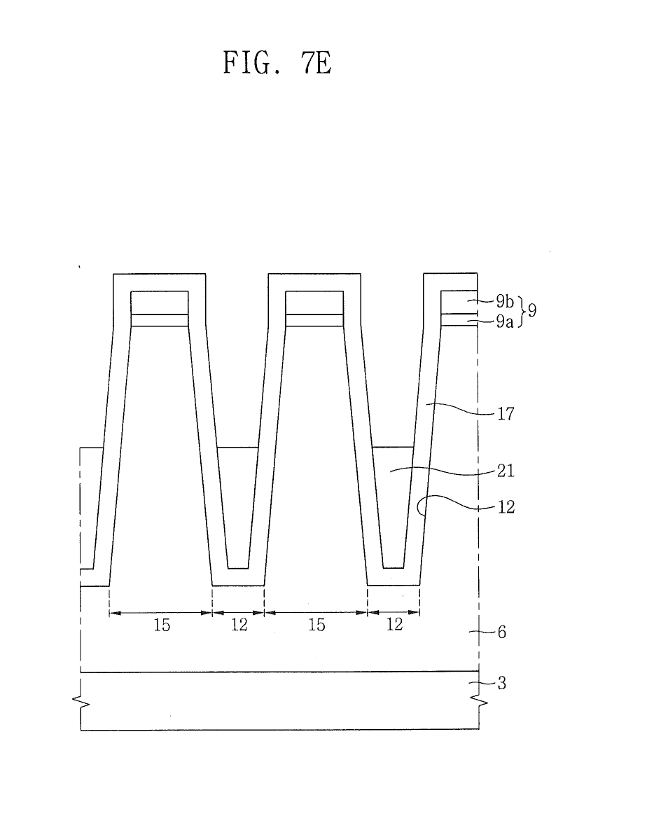

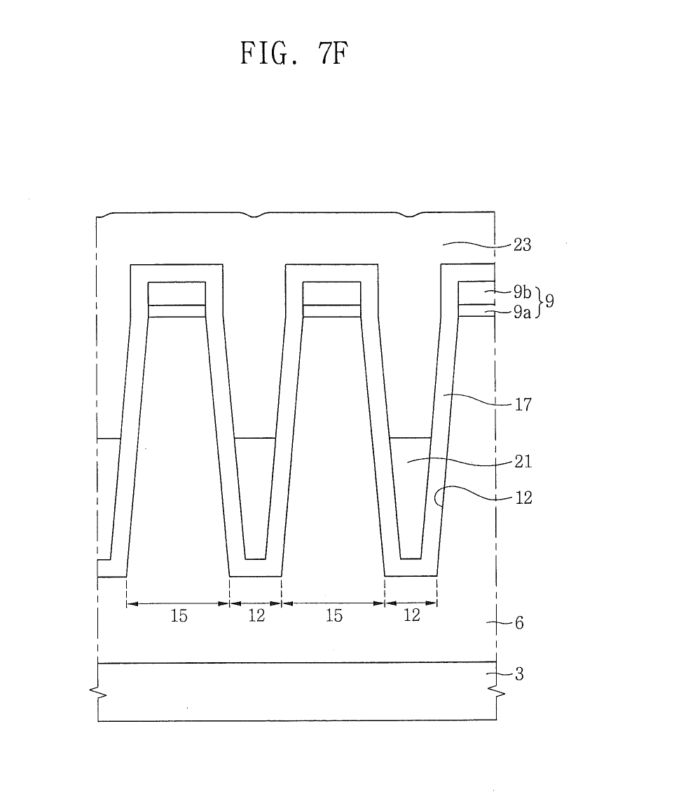

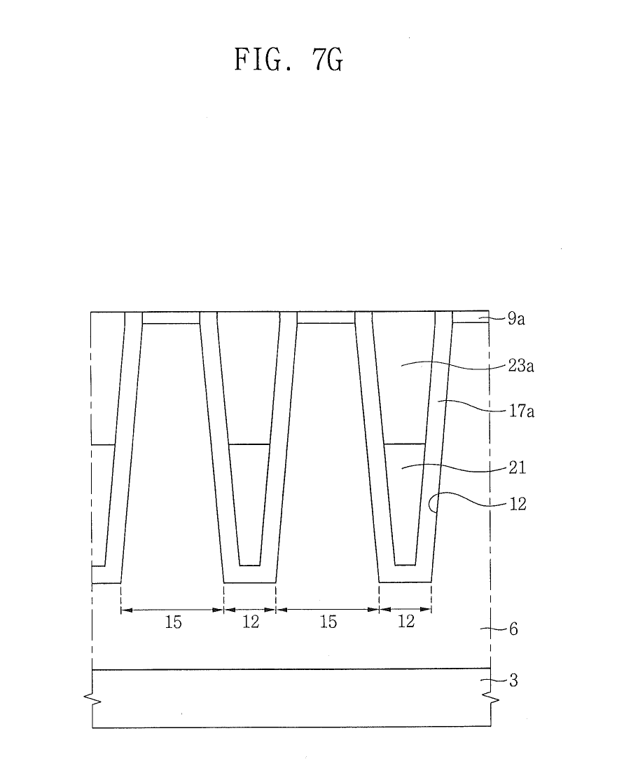

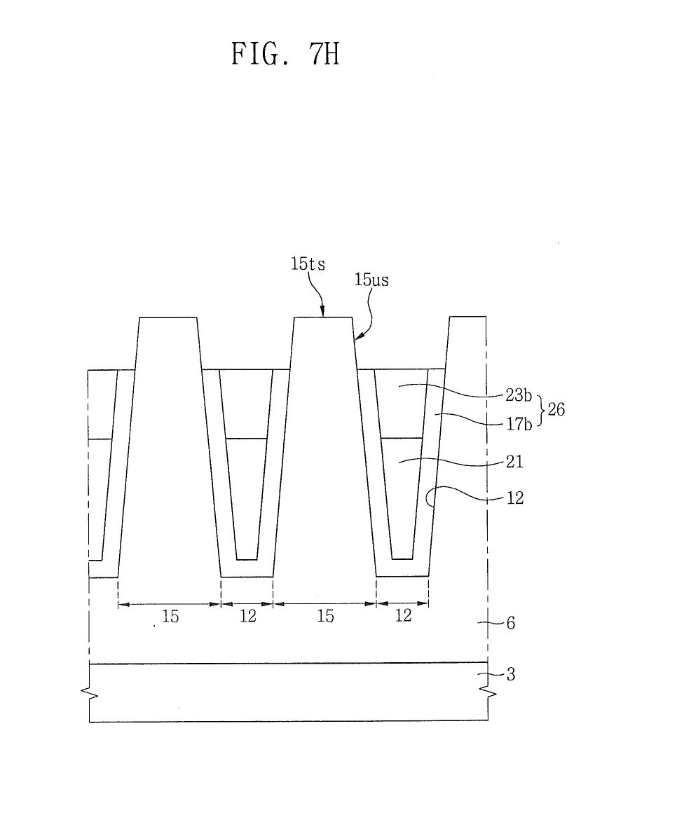

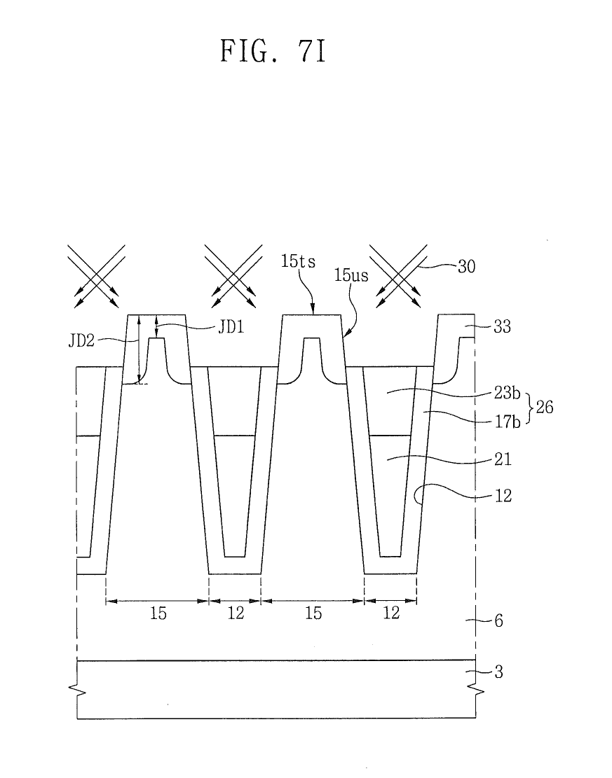

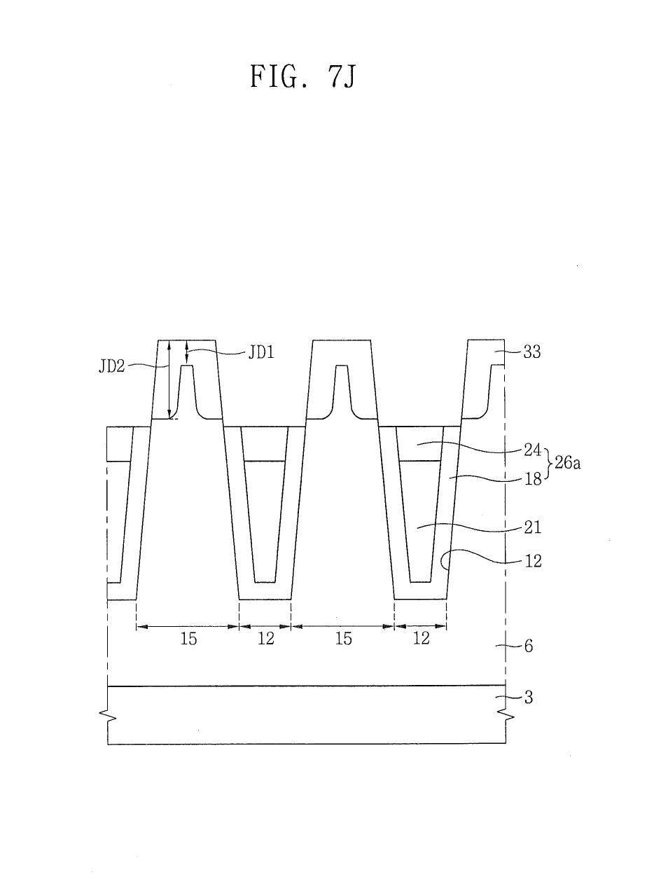

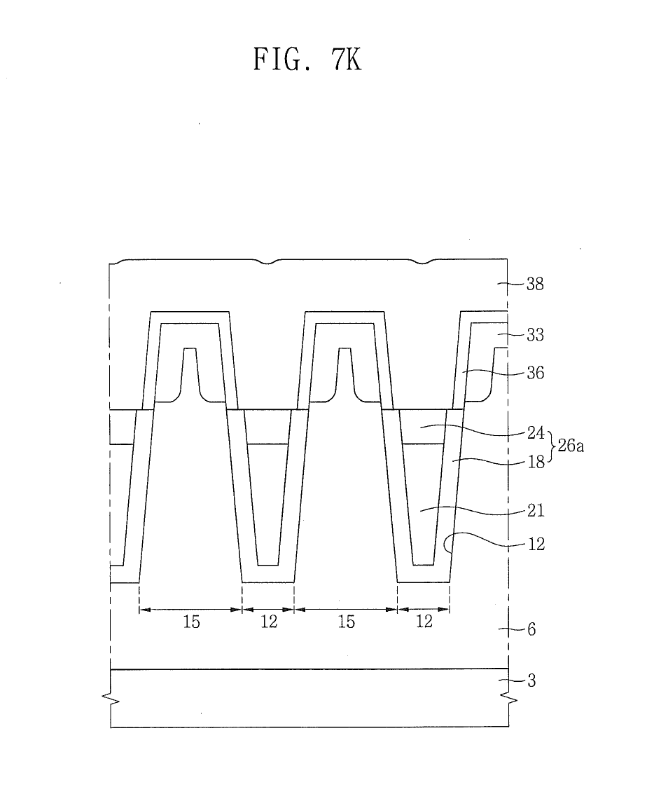

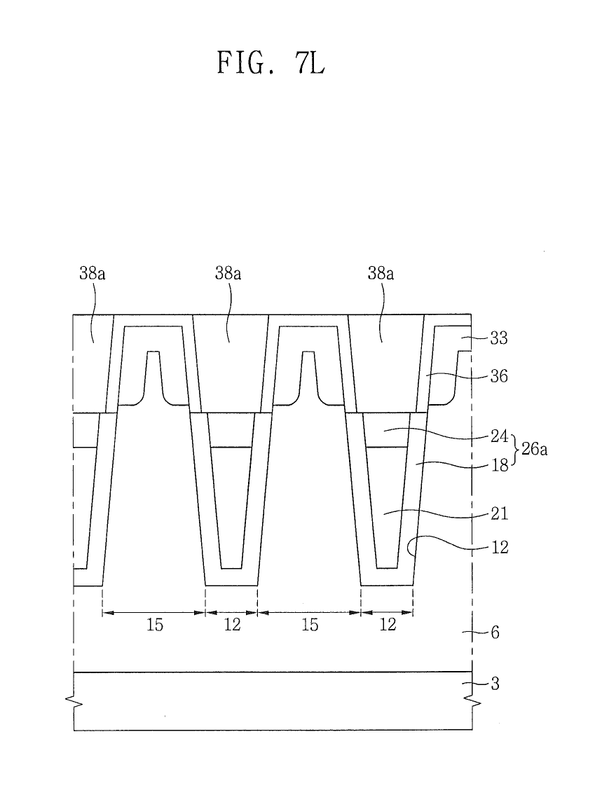

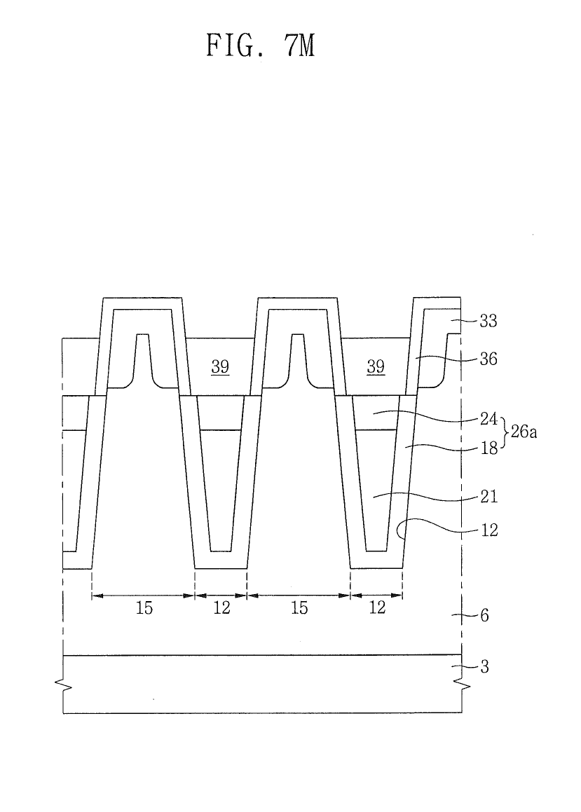

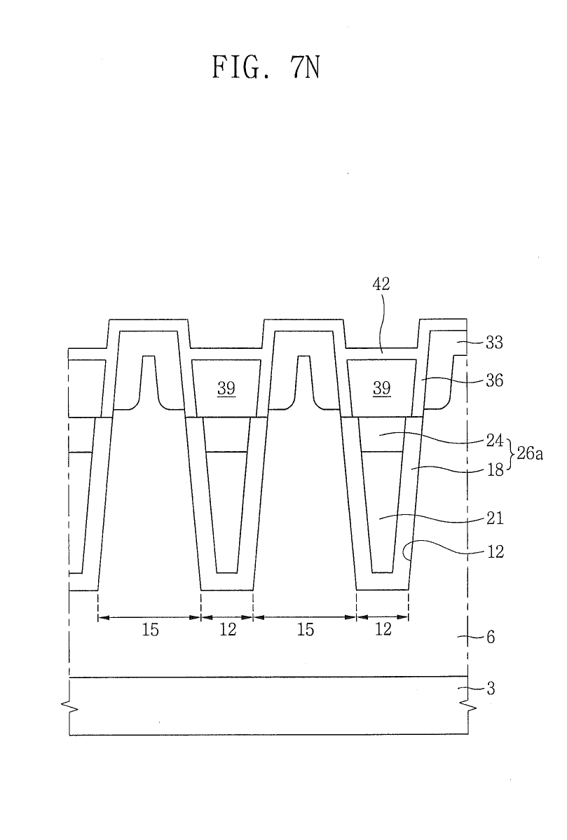

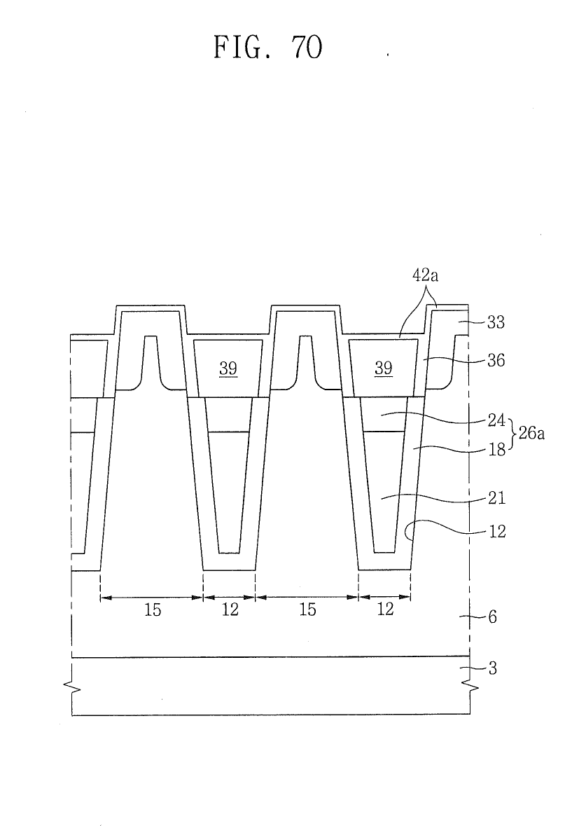

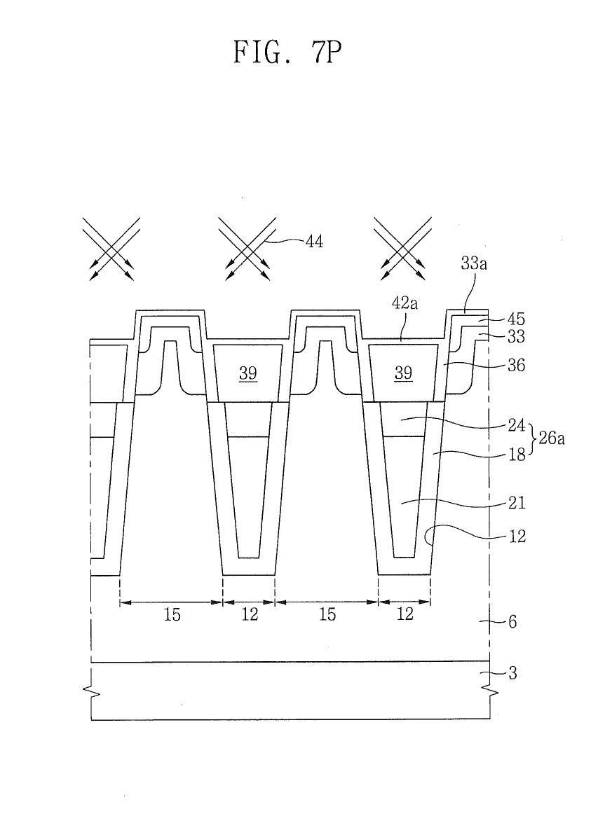

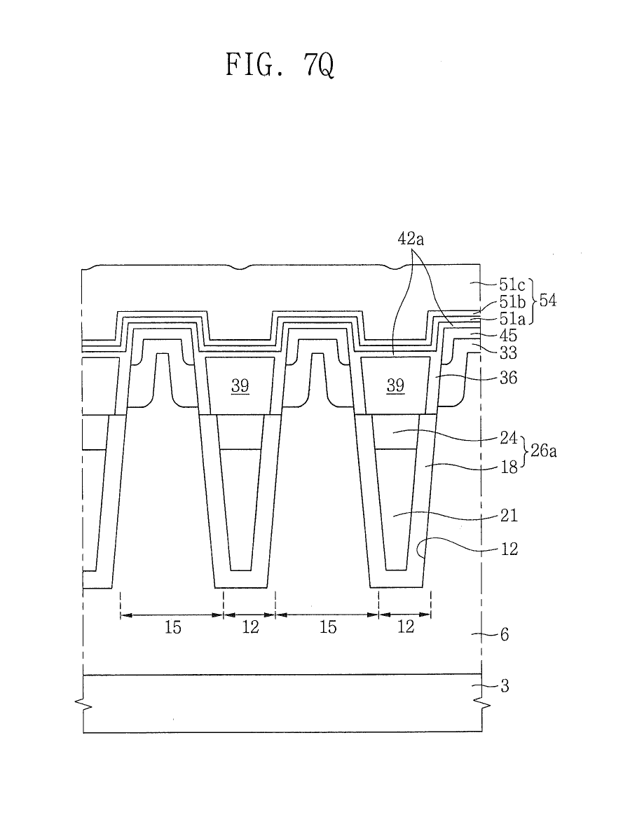

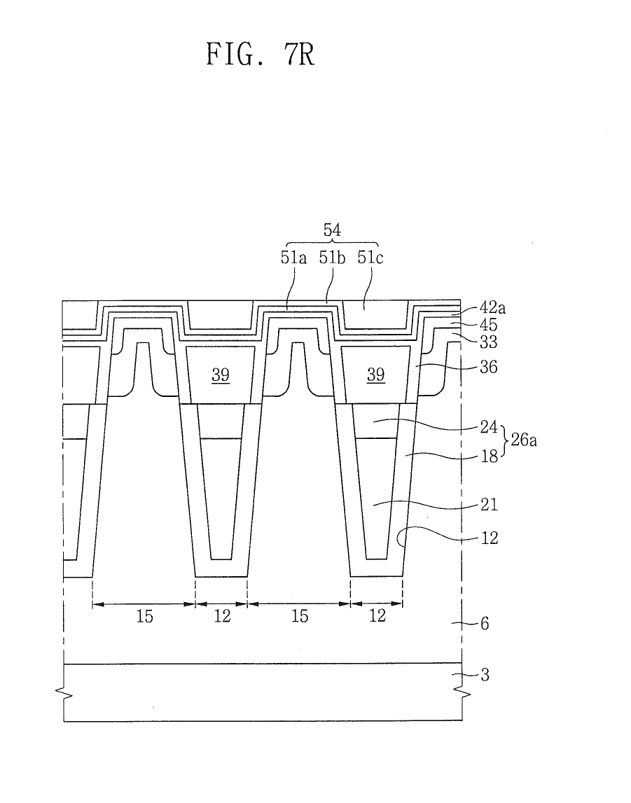

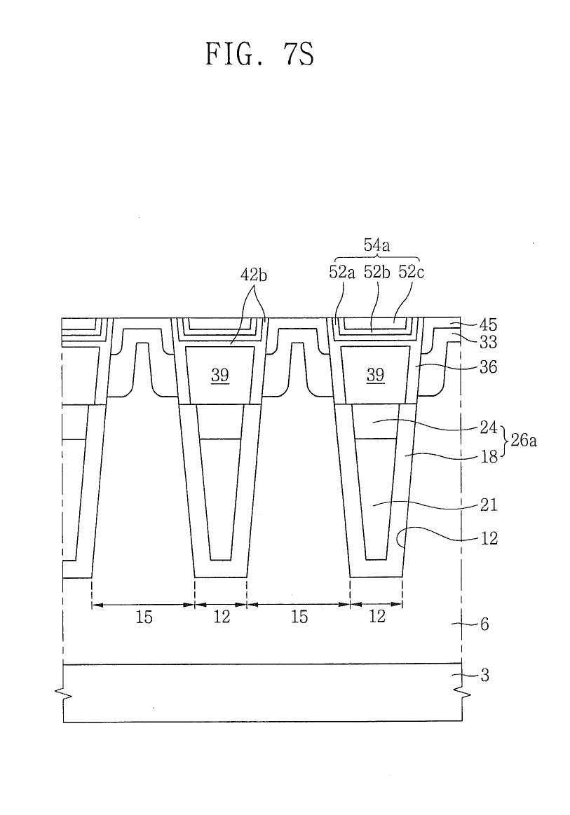

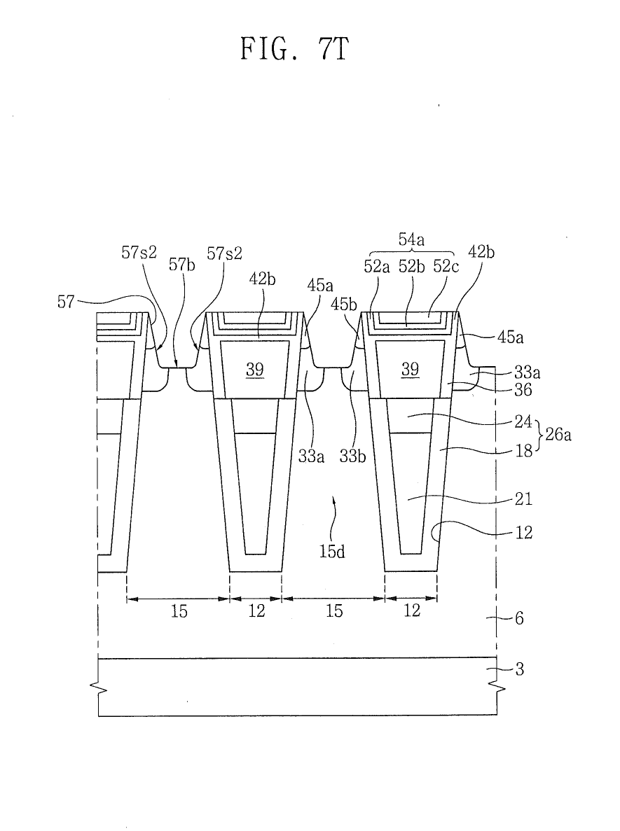

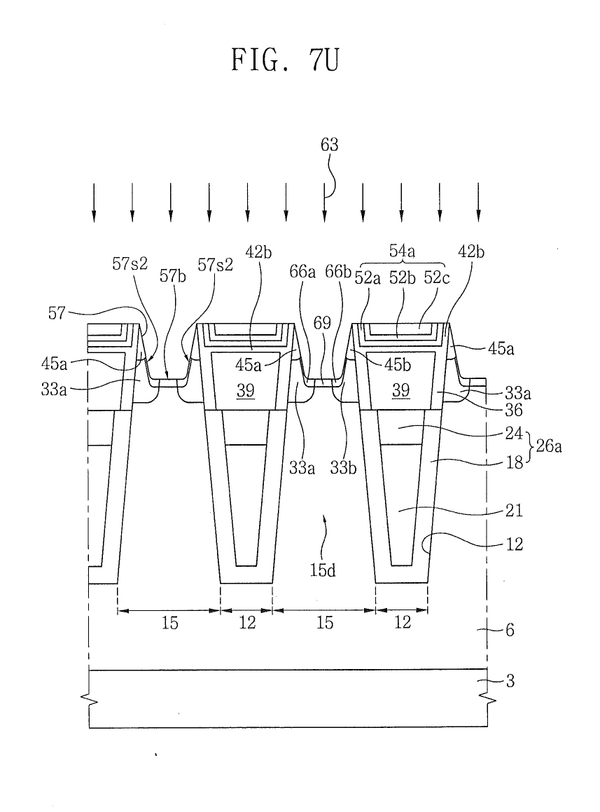

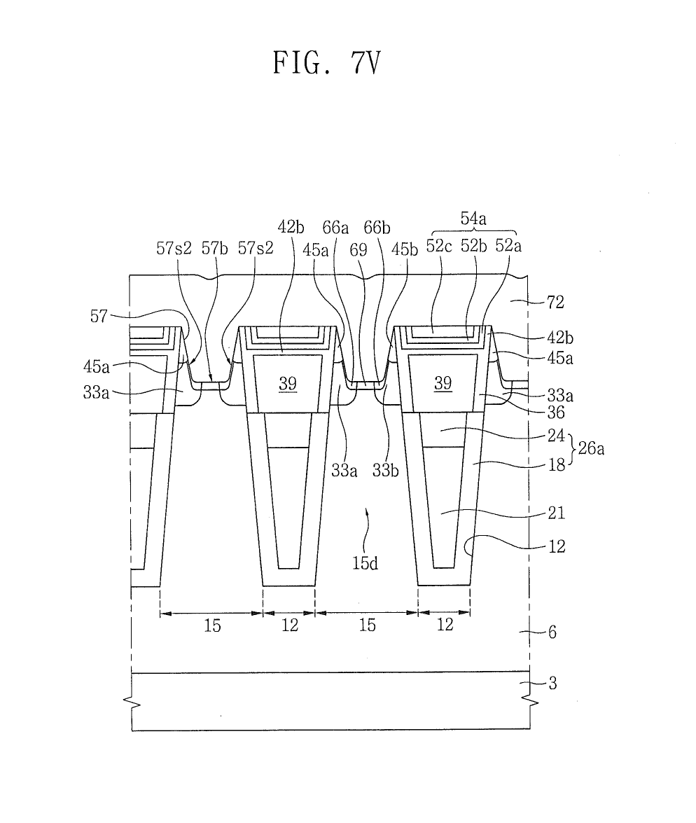

An exemplary embodiment of a method of fabricating the semiconductor device 1a described with reference to FIGS. 1A and 1B will be described with reference to FIGS. 7A to 7W.

Referring to FIG. 7A, a semiconductor substrate 3 may be provided. The semiconductor substrate 3 may have a first conductivity type. For example, the semiconductor substrate 3 may be an N-type silicon semiconductor wafer.

A semiconductor layer 6 may be formed on a front side of the semiconductor substrate 3. The semiconductor layer 6 may have the same conductivity type as the semiconductor substrate 3, but a lower impurity concentration than the semiconductor substrate 3. For example, when the semiconductor substrate 3 has N-type conductivity, the semiconductor layer 6 may have the same N-type conductivity as the semiconductor substrate 3, but a lower N-type impurity concentration than the semiconductor substrate 3. The semiconductor layer 6 may be formed in a single layer using an epitaxial growth process.

Referring to FIG. 7B, a trench region 12 defining an active region 15 may be formed in the semiconductor layer 6.

The formation of the trench region 12 may include forming a mask pattern 9 on the semiconductor layer 6, and etching the semiconductor layer 6 using the mask pattern 9 as an etch mask. The trench region 12 may be formed to surround the active region 15. A plurality of active regions 15 may be defined by the trench region 12.

The trench region 12 may narrow downwardly. Accordingly, the active region 15 may narrow upwardly. The active region 15 may include a first side surface (sidewall) and a second side surface (sidewall) facing each other. The first and second side surfaces of the active region 15 may be tapered.

The mask pattern 9 may include a lower mask pattern 9a and an upper mask pattern 9b which are sequentially stacked. The lower mask pattern 9a may be formed of silicon nitride, and the upper mask pattern 9b may be formed of silicon oxide.

Referring to FIG. 7C, a first insulating layer 17 may be formed on the substrate having the trench region 12. The first insulating layer 17 may be conformally formed. The first insulating layer 17 may be formed of silicon oxide. A shield conductive layer 20 may be formed on the substrate having the first insulating layer 17. The shield conductive layer 20 may be formed of a conductive material such as polysilicon.

Referring to FIG. 7D, a planarized shield conductive layer 20a may be formed by planarizing the shield conductive layer 20. For example, the formation of the planarized shield conductive layer 20a may include planarizing the shield conductive layer 20 by performing a planarization process using the first insulating layer 17 as a planarization-stopping layer. The planarization process may be a chemical mechanical polishing (CMP) process.

Referring to FIG. 7E, the planarized shield conductive layer 20a may be selectively etched to form a shield conductive pattern 21 partially filling the trench region 12 so that the shield conductive pattern 21 is at a lower level than an upper surface of the active region 15.

Referring to FIG. 7F, a second insulating layer 23 may be formed on the substrate having the shield conductive pattern 21. The second insulating layer 23 may be formed of an insulating material such as silicon oxide.

Referring to FIG. 7G, the second insulating layer 23 and the first insulating layer 17 may be planarized by performing a planarization process using the lower mask pattern 9a as a planarization-stopping layer. The planarization process may be a CMP process. During the planarization process, the upper mask pattern 9b may be removed. In the planarization process, the second insulating layer 23 may form a planarized second insulating layer 23a, and the first insulating layer 17 may form a planarized first insulating layer 17a.

Referring to FIG. 7H, an upper side surface 15us of the active region 15 may be exposed by partially etching the planarized second insulating layer 23a and the planarized first insulating layer 17a. The planarized second insulating layer 23a and the planarized first insulating layer 17a may be etched together. The planarized second insulating layer 23a may be partially etched to form a preliminary second insulating pattern 23b, and the planarized first insulating layer 17a may be partially etched to form a preliminary first insulating pattern 17b. The preliminary first and second insulating pattern 17b and 23b may form a preliminary insulating structure 26. The preliminary insulating structure 26 may be formed in the trench region 12, to surround the shield conductive pattern 21.

An upper surface 15ts of the active region 15 may be exposed by removing the lower mask pattern 9a using an etching process.

Referring to FIG. 7I, a body impurity region 33 may be formed in the active region 15 by performing a body channel ion-implantation process 30.

The active region 15 may have a first conductivity type, and the body impurity region 33 may have a second conductivity type different from the first conductivity type. For example, the active region 15 may have N-type conductivity, and the body impurity region 33 may have P-type conductivity.

The body channel ion-implantation process 30 may be an angled ion-implantation process. For example, the body channel ion-implantation process 30 may include obliquely injecting a 13th group element of the long-form Periodic Table, such as boron, into the active region 15. An angle or a slope of impurities injected by the body channel ion-implantation process 30 may be about 10° or more with respect to a surface of the semiconductor substrate 3 or the upper surface 15ts of the active region 15.

The body impurity region 33 may include a part having a first junction depth JD1 from the upper surface 15ts of the active region 15, and a part having a second junction depth JD2 from the upper surface 15ts of the active region 15. In the body impurity region 33, the part having the second junction depth JD2 may be closer to the trench regions 12 than the part having the first junction depth JD1.

Referring to FIG. 7J, an insulating structure 26a may be formed by partially etching the preliminary insulating structure 26. The insulating structure 26a may surround the shield conductive pattern 21, partially fill the trench regions 12, and be located at a lower level than the body impurity region 33. The body impurity region 33 and the insulating structure 26a may be spaced apart from each other,

Referring to FIG. 7K, a gate dielectric 36 may be formed on an upper portion of the active region 15 exposed while forming the insulating structure 26a. The gate dielectric 36 may be formed of silicon oxide. For example, the formation of the gate dielectric 36 may include oxidizing the exposed part of the active region 15.

A gate conductive layer 38 may be formed on the substrate having the gate dielectric 36. The gate conductive layer 38 may be formed of a conductive material such as polysilicon.

Referring to FIG. 7L, a planarized gate conductive layer 38a may be formed by planarizing the gate conductive layer 38, For example, the gate conductive layer 38 may be planarized by performing a CMP process using the gate dielectric 36 disposed on the upper surface of the active region 15 as a planarization-stopping layer. The gate dielectric 36 located on the upper surface of the active region 15 may prevent the upper surface of the active region 15 from being damaged by the CMP process.

Referring to FIG. 7M, a gate electrode 39 may be formed by partially etching the planarized gate conductive layer 38a to a level that is lower than the upper surface of the active region 15.

Since an upper surface of the insulating structure 26a is formed at a lower level than the body impurity region 33, the gate electrode 39 may horizontally overlap a part of the active region 15 located under the body impurity region 33.

Since the formation of the gate electrode 39 may include partially etching the planarized gate conductive layer 38a after planarizing the gate conductive layer 38 using the CMP process, an upper surface of the gate electrode 39 may be substantially flat, and dispersion characteristics of the gate electrode 39 may be improved.

In addition, since the shield conductive pattern 21 and the insulating structure 26a are formed together using a CMP process and an etching process before forming the gate electrode 39, the upper surface of the insulating structure 26a may be substantially flat. Accordingly, a lower surface of the gate electrode 39 formed on the insulating structure 26a having the flat upper surface may be substantially flat.

Accordingly, since the gate electrode 39 having the substantially flat upper and lower surfaces is provided, dispersion characteristics of a semiconductor device including the gate electrode 39 may be improved.

Referring to FIG. 7N, a silicon oxide layer 42 may be formed on the upper surface of the gate electrode 39. The silicon oxide layer 42 may be formed by oxidizing the exposed part of the polysilicon gate electrode 39. When the gate dielectric 36 is formed of silicon oxide using an oxidation process, and the silicon oxide layer 42 is formed using an oxidation process, the boundary between the silicon oxide layer 42 and the gate dielectric 36 may not be clearly defined.

Referring to FIG. 7O, an insulating buffer layer 42a may be formed by partially etching the gate dielectric 36 and the silicon oxide layer 42 using an isotropic etching process. Accordingly, the insulating buffer layer 42a may include a part in which the thickness of the gate dielectric 36 located at a higher level than the gate electrode 39 is reduced, and a part in which the thickness of the silicon oxide layer 42 is reduced.

Referring to FIG. 7P, a source impurity area 45 may be formed in the active region 15 using a source ion-implantation process 44. The source impurity area 45 may have a different conductivity type from the body impurity region 33. For example, when the body impurity region 33 has P-type conductivity, the source impurity area 45 may be formed to have N-type conductivity by injecting a 15th group element of the long-form Periodic Table, such as P and As, into the upper portion of the active region 15.

The source ion-implantation process 44 may be performed with lower ion-implantation energy than the body channel ion-implantation process 30. Accordingly, the source impurity area 45 may be formed to have a shallower junction structure than the body impurity region 33. The source impurity area 45 may be formed in the body impurity region 33.

The source ion-implantation process 44 may be performed using an angled ion-implantation process. Accordingly, the source ion-implantation process 44 may include obliquely injecting a 15th group element of the long-form Periodic Table, such as P or As, with respect to the surface of the semiconductor substrate 3 and the upper surface of the active region 15.

Referring to FIG. 7Q, a first insulating capping layer 51a may be conformally formed on the semiconductor substrate in which the source impurity area 45 is formed. The first insulating capping layer 51a may be formed of silicon oxide. A second insulating capping layer 51b may be conformally formed on the first insulating capping layer 51a. A third insulating capping layer 51c may be conformally formed on the second insulating capping layer 51b. The third insulating capping layer 51c may be formed thicker than the first and second insulating capping layers 51a and 51b. The second insulating capping layer 51b may be formed of a material having an etch selectivity with respect to the third insulating capping layer 51c. For example, the third insulating capping layer 51c may be formed of a silicon oxide layer, and the second insulating capping layer 51b may be formed of a silicon nitride layer. The first to third insulating capping layers 51a, 51b, and 51c may form a gate capping layer 54.

Referring to FIG. 7R, the third insulating capping layer 51c may be planarized until the second insulating capping layer 51b located on the upper surface of the active region 15 is exposed. For example, the third insulating capping layer 51c may be planarized by performing a CMP process using the second insulating capping layer 51b located on the upper surface of the active region 15 as a planarization-stopping layer.

Referring to FIG. 7S, the second insulating capping layer 51b, the first insulating capping layer 51a, and the insulating buffer layer 42a which are located on the upper surface of the active region 15, may be removed using an etching process. Accordingly, the upper surface of the active region 15 may be exposed.

The gate capping layer 54 may remain on the gate electrode 39 to form a gate capping pattern 54a, The insulating buffer layer 42a may remain to form an insulating buffer pattern 42b surrounding side and bottom surfaces of the gate capping pattern 54a.

The gate capping pattern 54a may be formed by sequentially performing a CMP process and an etching process with respect to the gate capping layer 54, using the second insulating capping layer 51b as a CMP stopping layer. Accordingly, an upper surface of the gate capping pattern 54a becomes substantially flat with no damage in the upper surface of the active region 15.

Referring to FIG. 7T, a groove region 57 may be formed by etching the upper surface of the active region 15. The groove region 57 may be formed to have tapered sidewalls 57s 1 and 57s2. The groove region 57 may be formed to have the tapered sidewalls 57s1 and 57s2, and substantially flat bottom surface 57b.

The groove region 57 may sequentially pass through the source impurity area 45 and the body impurity region 33 in the active region 15. The source impurity area 45 may include a first source region 45a and a second source region 45b spaced apart from each other by the groove region 57. The body impurity region 33 may include a first body channel region 33a and a second body channel region 33b spaced apart from each other by the groove region 57.

Bottom surfaces of the first and second body channel regions 33a and 33b may be formed at a lower level than the groove region 57.

Referring to FIG. 7U, first and second body contact regions 66a and 66b, and a Schottky semiconductor region 69 may be formed by performing an additional ion-implantation process 63.

The Schottky semiconductor region 69 may be formed in active region 15 located between the first and second body channel regions 33a and 33b and under the bottom surface 57b of the groove region 57.

The first body contact region 66a may be formed in the first body channel region 33a exposed by the groove region 57, and the second body contact region 66b may be formed in the second body channel region 33b exposed by the groove region 57. The Schottky semiconductor region 69 may be located between the first and second body contact regions 66a and 66b.

The additional ion-implantation process 63 may be performed in such a way that impurity ions are injected in the direction perpendicular to the semiconductor substrate 3.

When the first and second body channel regions 33a and 33b have P-type conductivity, and the active region 15 has N-type conductivity, the additional ion-implantation process 63 may be a process of injecting a 13th group element of the long-form Periodic Table, such as boron, into the first and second body channel regions 33a and 33b and the active region 15. The Schottky semiconductor region 69 may have N-type conductivity, and the first and second body contact regions 66a and 66b may have P-type conductivity.

The amount per unit volume of 13th group element of the long-form Periodic Table, which is injected by the additional ion-implantation process 63, may be smaller than the amount per unit volume of the 15th group element of the long-form Periodic Table in the active region 15. Accordingly, a part of the active region 15 disposed between the first and second body channel regions 33a and 33b may form the Schottky semiconductor region 66 by the additional ion-implantation process 63, and the Schottky semiconductor region 66 may have a lower majority carrier or donor concentration than the active region 15. Accordingly, the Schottky semiconductor region 66 may include both 13th and 15th group elements of the long-form Periodic Table, and the content of the 15th group element may be greater than the content of the 13th group element.

In some embodiments, the amount per unit volume of the 13th group element of the long-form Periodic Table which is injected into the active region 15 by the additional ion-implantation process 63, may be greater than the amount per unit volume of the 15th group element of the long-form Periodic Table which is injected into the active region 15 by the body channel ion-implantation process 30.

Referring to FIG. 7V, a front-side conductive pattern 72 is formed to fill the groove region 57 and overlap the gate electrode 39. The front-side conductive pattern 72 may form an ohmic contact with the first and second source regions 45a and 45b. The front-side conductive pattern 72 may form ohmic contacts with the first and second body contact regions 66a and 66b. The front-side conductive pattern 72 may form a Schottky diode with the Schottky semiconductor region 69.

Referring again to FIGS. 1A and 1B, the back side 3bs of the semiconductor substrate 3 may be ground to reduce the thickness of the semiconductor substrate 3. Next, a back-side conductive layer 80 may be formed on the back side of the semiconductor substrate 3 having the reduced thickness. Accordingly, the semiconductor device 1a as described in FIGS. 1A and 1B may be formed.

The Schottky semiconductor region 69 is embedded between the first and second transistors TR1a and TR2a. Further, the first and second gate electrodes 39 can be configured together to provide a split-gate for the combination of the first and second transistors TR1a and TR2a outputs a single split-gate power MOSFET in some embodiments according to the invention. As appreciated by the present inventors, since the Schottky diode has a lower _{VSD} value than the body diode, dead time and power loss may be reduced.

According to some embodiments of the inventive concept, a power MOSFET device can include both a split gate arrangement and an embedded Schottky diode.

Next, an exemplary embodiment of a method of fabricating the semiconductor device 1b described with reference to FIG. 2 will be described with reference to FIGS. 7A to 7E.

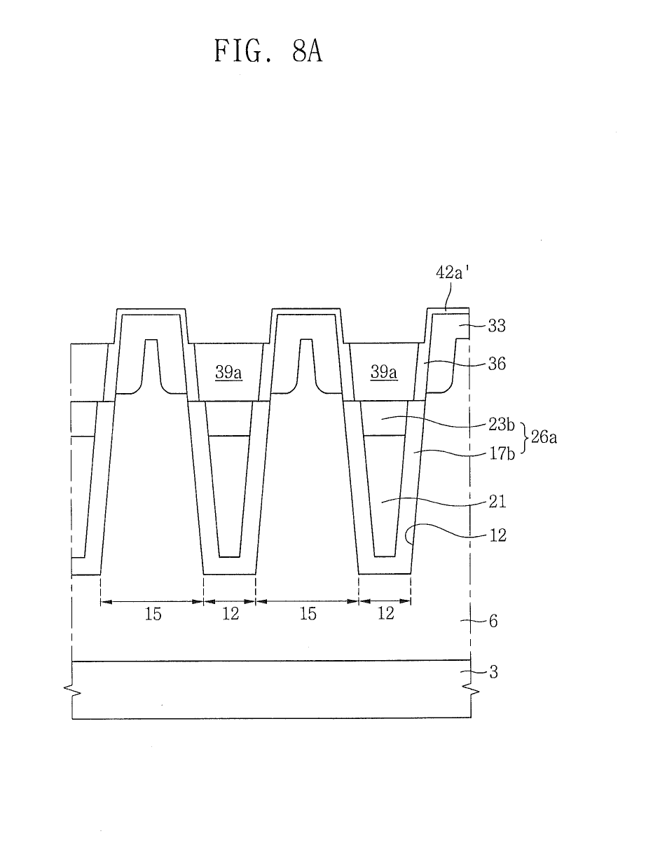

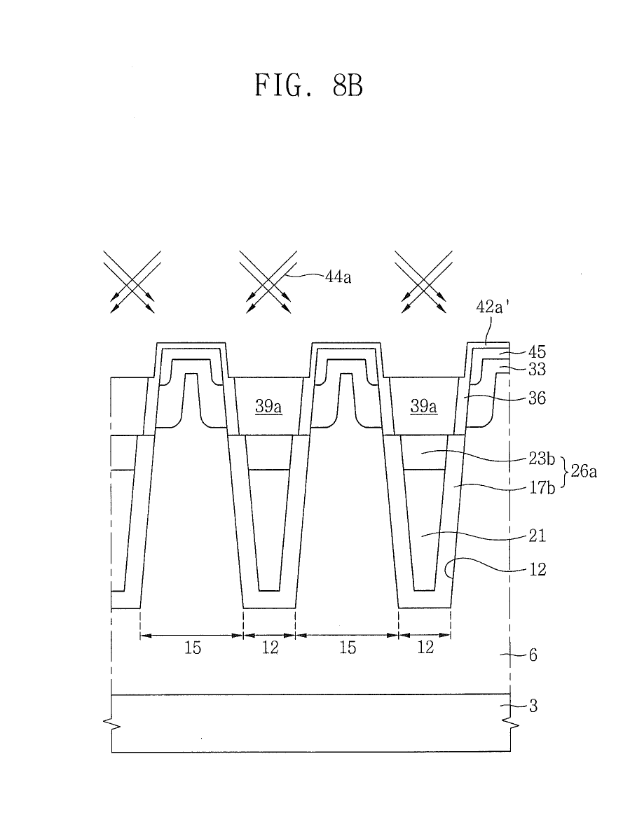

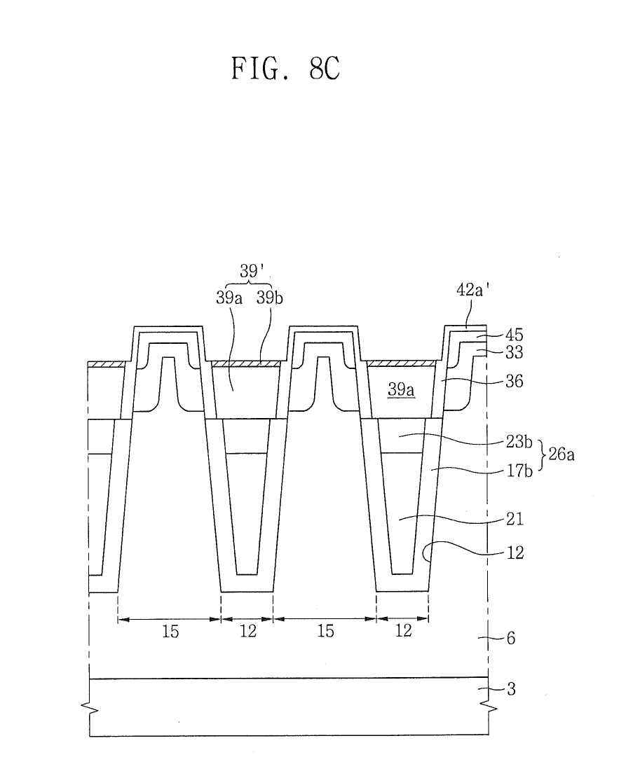

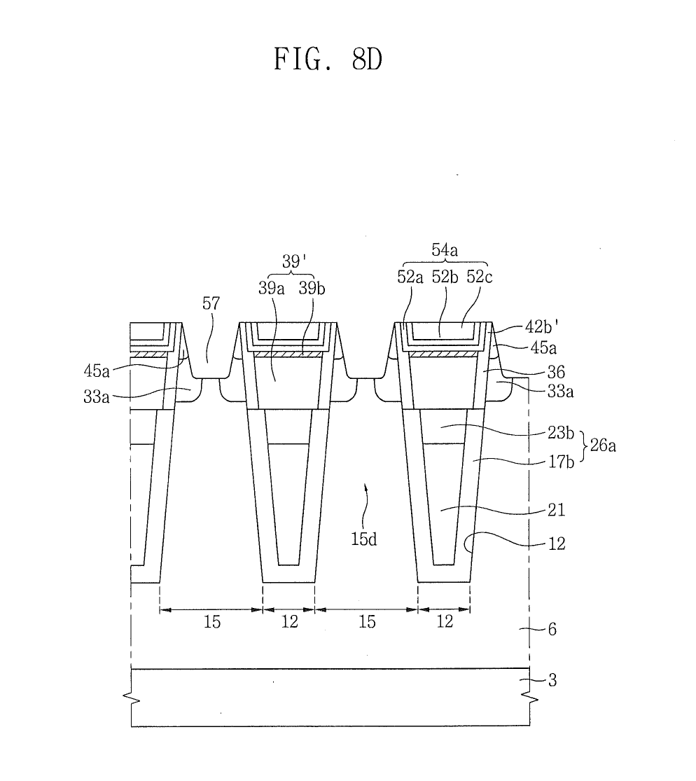

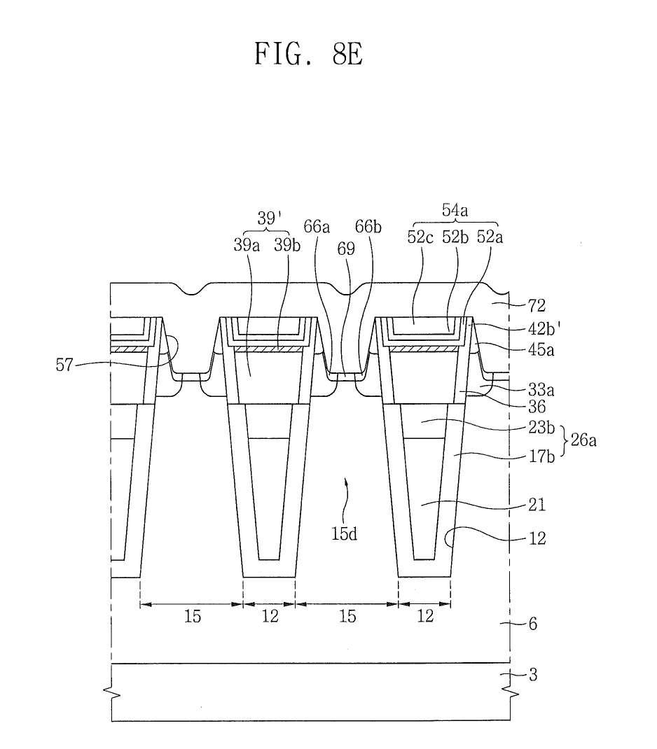

Referring to FIG. 8A, the trench region 12 defining the active region 15 may be formed in the semiconductor layer 6 of the semiconductor substrate 3, as described with reference to FIGS. 7A and 7B.

As described with reference to FIGS. 7C to 7H, the shield conductive pattern 21 and the preliminary insulating structure 26 which partially fill the trench region 12, may be formed. As described with reference to FIG. 7I, the body impurity region 33 may be formed in the upper portion of the active region 15 in the body channel ion-implantation process 30. As described with reference to FIG. 7J, the insulating structure 26a may be formed by partially etching the preliminary insulating structure 26. Further, as described with reference to FIG. 7K, the gate dielectric 36 may be formed on the exposed surface of the active region 15. Next, a polysilicon pattern 39a may be formed using substantially the same method as the gate electrode 39 described in FIGS. 7K to 7M.

After the polysilicon pattern 39a is formed, a partial etching process may be performed to reduce the thickness of the exposed part of the gate dielectric 36. Accordingly, the thickness of the gate dielectric 36 located at a higher level than the polysilicon pattern 39a may be reduced. The gate dielectric 36 having the reduced thickness may be defined as an insulating buffer layer 42a′.

Referring to FIG. 8B, the source impurity area, 45 as described in FIG. 7P may be formed by performing a source ion-implantation process 44a as described in FIG. 7P.

Referring to FIG. 8C, a metal-semiconductor compound layer 39b may be formed on an exposed surface of the polysilicon pattern 39a. The metal-semiconductor compound layer 39b may be formed of a silicide, such as CoSi, NiSi, and WSi.

Referring to FIG. 8D, the insulating capping pattern 54a as described with reference to FIGS. 7Q to 7S may be formed on the substrate having the metal-semiconductor compound layer 39b. Next, the groove region 57, the first and second source regions 45a and 45b, and the first and second body channel regions 33a and 33b as described with reference to FIG. 7T may be formed.

Referring to FIG. 8E, the Schottky semiconductor region 69 and the first and second body contact regions 66a and 66b which are described in FIG. 7U may be formed by performing the additional ion-implantation process 63 as described with reference to FIG. 7U. Next, as described with reference to FIG. 7V, the front-side conductive pattern 72 filling the groove region 57 and covering the insulating capping pattern 54a, may be formed.

Referring again to FIG. 2, the back side 3bs of the semiconductor substrate 3 may be ground to reduce the thickness of the semiconductor substrate 3. Next, a back-side conductive layer 80 may be formed on the back side of the semiconductor substrate 3 having the reduced thickness. Accordingly, the semiconductor device 1b as described in FIG. 2 may be formed.

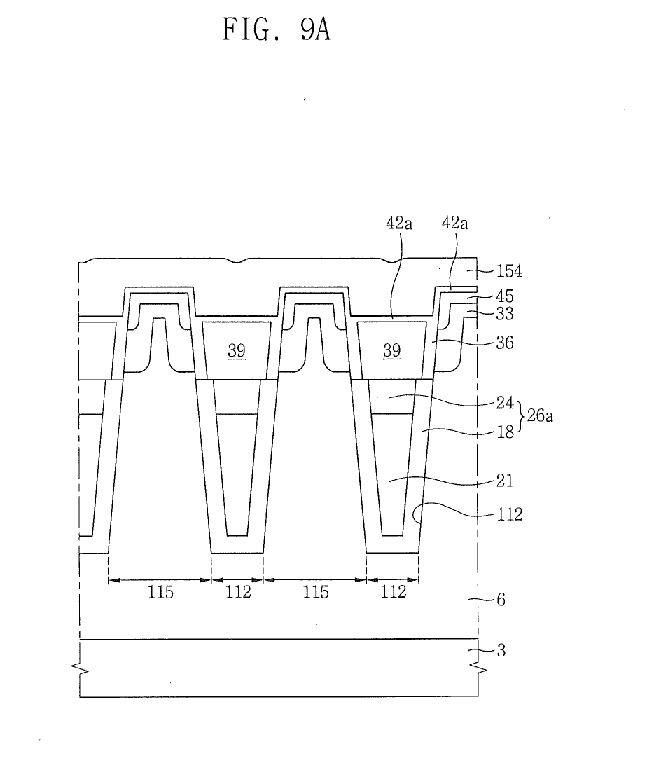

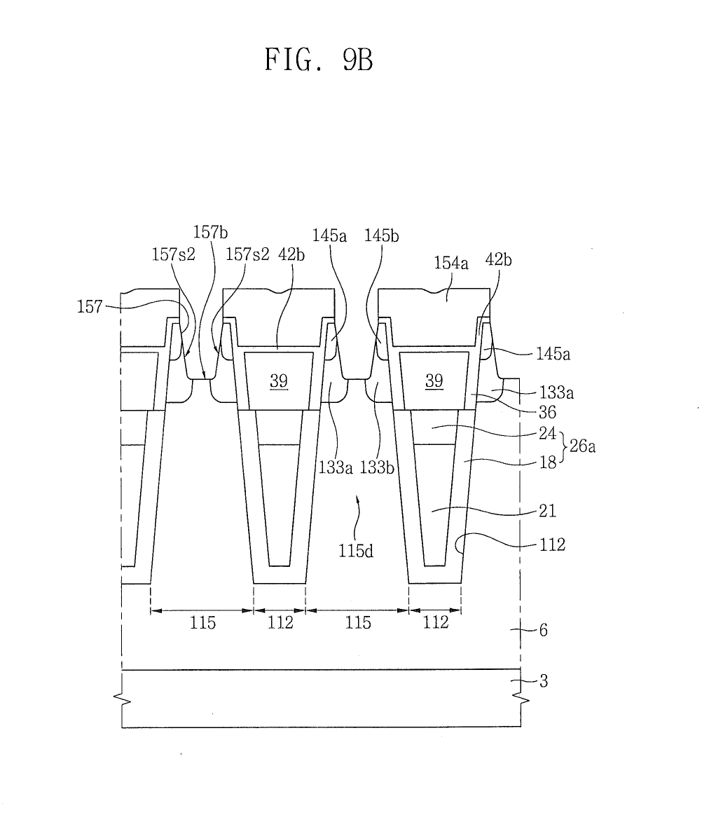

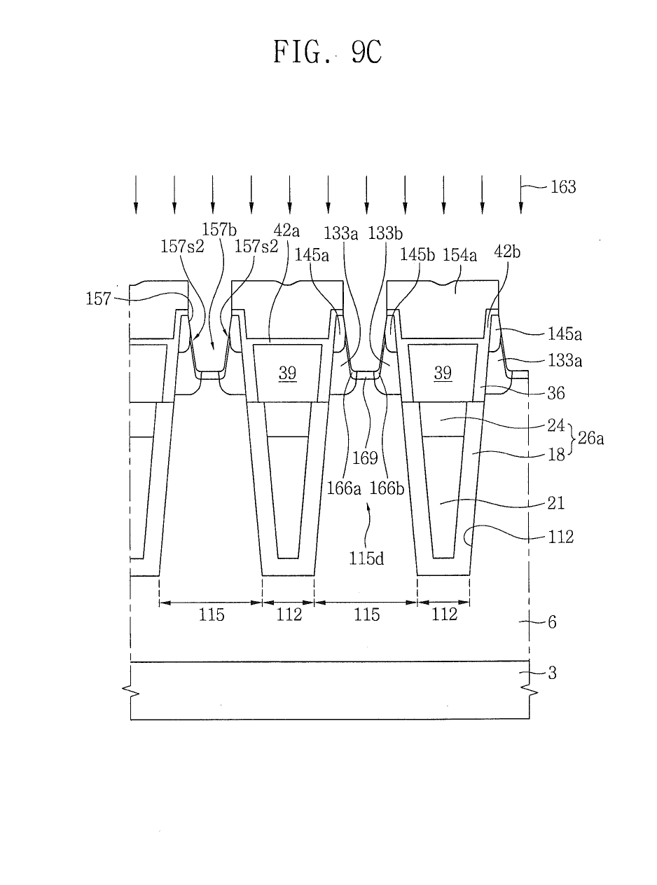

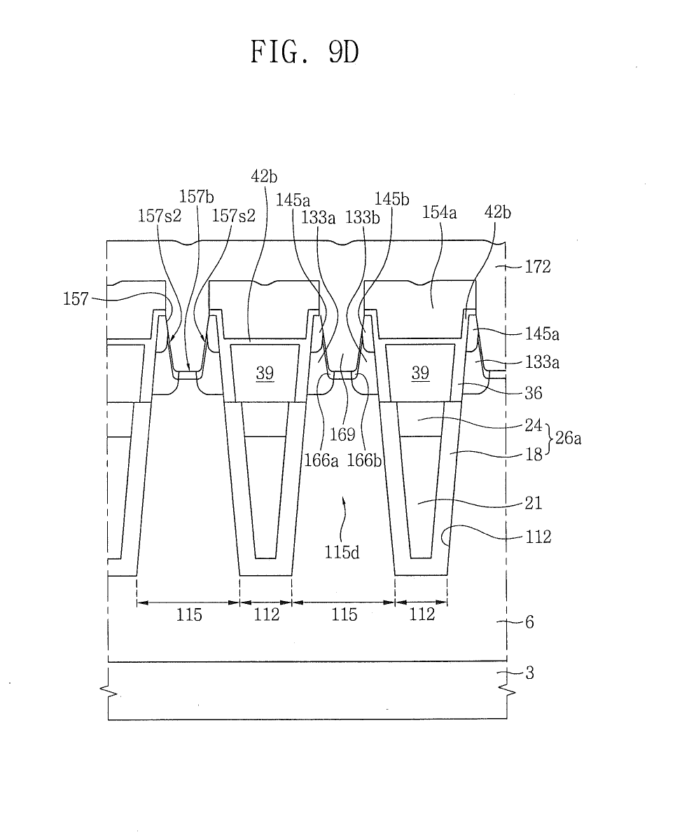

Next, an exemplary embodiment of a method of fabricating the semiconductor device 100a described with reference to FIGS. 3A and 3B will be described with reference to FIGS. 9A to 9D.

Referring to FIG. 9A, the semiconductor layer 6 may be formed on the semiconductor substrate 3, as described with reference to FIG. 7A. A trench region 112 defining an active region 115 may be formed in the semiconductor layer 6. The active region 115 may be formed to have a tapered side surface like the active region 15 described in FIG. 7B.

As described with reference to FIGS. 7C to 7H, the shield conductive pattern 21 and the preliminary insulating structure 26 which partially fill the trench region 112, may be formed.

As described with reference to FIG. 7I, the body impurity region 33 may be formed in an upper portion of the active region 115 in the body channel ion-implantation process 30. As described with reference to FIG. 7J, the insulating structure 26a may be formed by partially etching the preliminary insulating structure 26. Further, as described with reference to FIG. 7K, the gate dielectric 36 may be formed on the exposed surface of the active region 115. Next, the gate electrode 39 described in FIGS. 7K to 7M may be formed. Next, the insulating buffer layer 42a may be formed as described in FIG. 7O, and the source impurity area 45 may be formed as described with reference to FIG. 7B.

An insulating capping layer 154 may be formed on the substrate having the source impurity area 45. The insulating capping layer 154 may be formed of an insulating material such as silicon oxide.

Referring to FIG. 9B, insulating capping patterns 154a may be formed by patterning the insulating capping layer 154. Next, insulating buffer patterns 42b may be formed by etching the insulating buffer layer 42a under the insulating capping patterns 154a. The insulating capping patterns 154a may overlap parts of the upper surface of the active region 115.

A groove region 157 may be formed by partially etching the active region 115 using the insulating capping patterns 154a as an etch mask. The groove region 157 may include tapered sidewalls 157s1 and 157s2, and a bottom surface 157b. First and second active protrusions spaced apart from each other by the groove region 157 may be formed on an upper portion of the active region 115.

The groove region 157 may pass through the source impurity area 45 and the body impurity region 33. The source impurity area 45 may form a first source region 145a and a second source region 145b spaced apart by the groove region 157, and the body impurity region 33 may form a first body channel region 133a and a second body channel region 133b spaced apart from each other by the groove region 157.

Referring to FIG. 9C, first and second body contact regions 166a and 166b, and a Schottky semiconductor region 169 substantially the same as the first and second body contact regions 66a and 66b and the Schottky semiconductor region 69 which are described in FIG. 7U may be formed by performing an additional ion-implantation process 163 like the additional ion-implantation process 63 described in FIG. 7U.

The Schottky semiconductor region 169 may be formed in the active region 115 located between the first and second body channel regions 133a and 133b, the first body contact region 166a may be formed in a surface of the first body channel region 133a exposed by the groove region 157, and the second body contact region 166b may be formed in a surface of the second body channel region 133b exposed by the groove region 157. The Schottky semiconductor region 169 may be located between the first and second body contact regions 166a and 166b.

The Schottky semiconductor region 169 is embedded between the first and second transistors TR1b and TR2b. Further, the first and second gate electrodes 39 can be configured together to provide a split-gate for the combination of the first and second transistors TR1b and TR2b outputs a single split-gate power MOSFET in some embodiments according to the invention. As appreciated by the present inventors, since the Schottky diode has a lower _{VSD} value than the body diode, dead time and power loss may be reduced.

According to some embodiments of the inventive concept, a power MOSFET device can include both a split gate arrangement and an embedded Schottky diode.

Referring to FIG. 9D, a front-side conductive pattern 172 filling the groove region 157 and covering the insulating capping patterns 154a may be formed.

Referring again to FIGS. 3A and 3B, the back side 3bs of the semiconductor substrate 3 may be ground to reduce the thickness of the semiconductor substrate 3. Next, a back-side conductive layer 180 may be formed on the back side 3bs of the semiconductor substrate 3 having the reduced thickness. Accordingly, the semiconductor device 100a as described in FIGS. 3A and 3B may be formed.

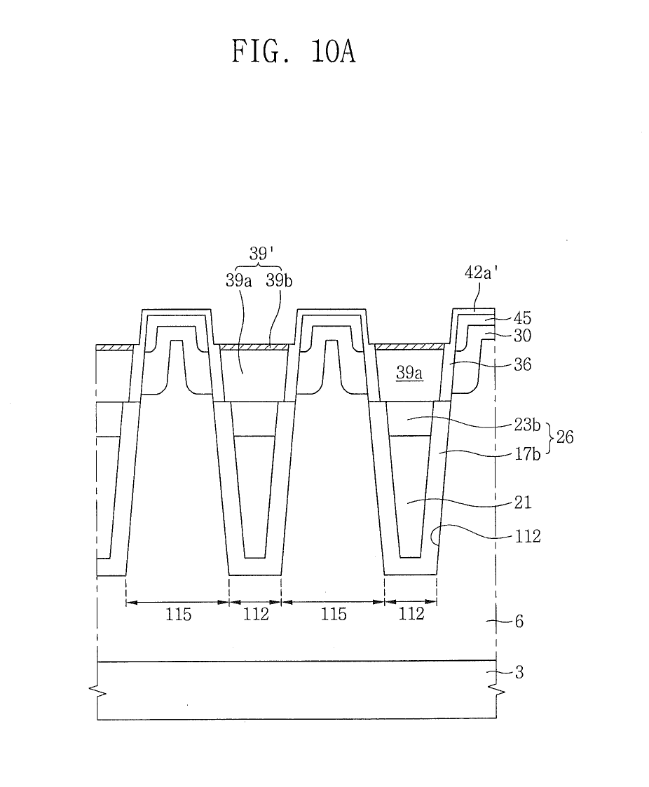

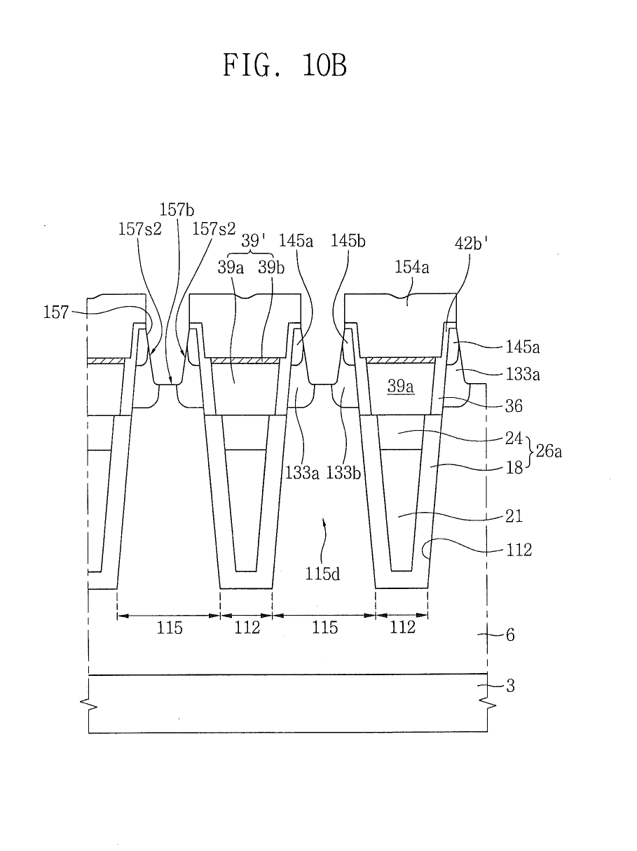

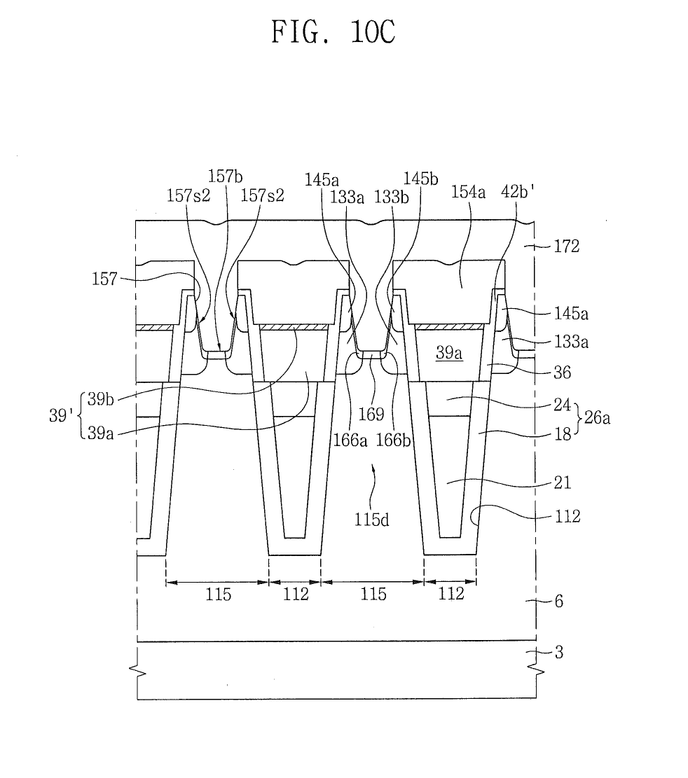

Next, an exemplary embodiment of a method of fabricating the semiconductor device 100b described with reference to FIG. 4 will be described with reference to FIGS. 10A to 10C.

Referring to FIG. 10A, the semiconductor layer 6 may be formed on the semiconductor substrate 3, as described with reference to FIGS. 7A and 7B. The trench region 112 defining the active region 115 having tapered side surfaces may be formed in the semiconductor layer 6. As described with reference to FIGS. 7C to 7H, the shield conductive pattern 21 and the preliminary insulating structure 26 which partially fill the trench region 112 may be formed. As described with reference to FIG. 7I, the body impurity region 33 may be formed in an upper portion of the active region 115 by performing the body channel ion-implantation process 30. As described with reference to FIG. 7J, the insulating structure 26a may be formed by partially etching the preliminary insulating structure 26. As described with reference to FIG. 7K, the gate dielectric 36 may be formed on the exposed surface of the active region 115. Next, a polysilicon pattern 39a may be formed using substantially the same method as the gate electrode 39 described in FIGS. 7K to 7M.

Next, as described with reference to FIG. 8A, after forming the polysilicon pattern 39a, an etching process may be performed to reduce the thickness of the exposed part of the gate dielectric 36. Accordingly, the thickness of the gate dielectric 36 located at a higher level than the polysilicon pattern 39a may be reduced. The gate dielectric 36 having the reduced thickness may be defined as an insulating buffer layer 42a′.

Next, a source impurity area 45 may be formed in the active region 115 by performing the source ion-implantation process 44a as described in FIG. 8B.

Next, as in FIG. 8C, and a metal-semiconductor compound layer 39b may be formed on an exposed surface of the polysilicon pattern 39a. The metal-semiconductor compound layer 39b may be formed of a silicide, such as CoSi, NiSi, and WSi.

Referring to FIG. 10B, the insulating capping layer 154 as described in FIG. 9A may be formed. Next, the insulating capping layer 154 may be patterned to form insulating capping patterns 154a. Next, the insulating buffer layer 42a under the insulating capping patterns 154a may be etched to form an insulating buffer pattern 42b, and the active region 115 may be partially etched to form a groove region 157. The groove region 157 may have tapered sidewalls 157s1 and 157s2, and a bottom surface 157b. First and second active protrusions spaced apart from each other by the groove region 157 may be formed on the upper portion of the active region 115.

The groove region 157 may pass through the source impurity area 45 and the body impurity region 33. A first source region 145a and a second source region 145b spaced apart from each other by the groove region 157 may be formed from the source impurity area 45, and a first body channel region 133a and a second body channel region 133b spaced apart from each other by the groove region 157 may be formed from the body impurity region 33.

Referring to FIG. 10C, first and second body contact regions 166a and 166b, and a Schottky semiconductor region 169 may be formed by performing the additional ion-implantation process 163 described in FIG. 9C. Next, the front-side conductive pattern 172 as described in FIG. 9D may be formed.

Referring again to FIG. 4, the back side 3bs of the semiconductor substrate 3 may be ground to reduce the thickness of the semiconductor substrate 3. Next, a back-side conductive layer 180 may be formed on the back side 3bs of the semiconductor substrate 3 having the reduced thickness.

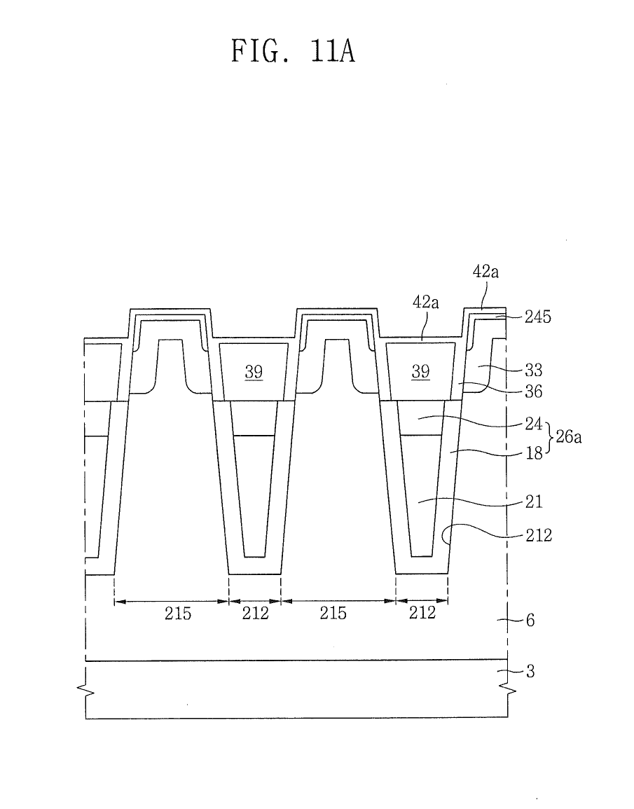

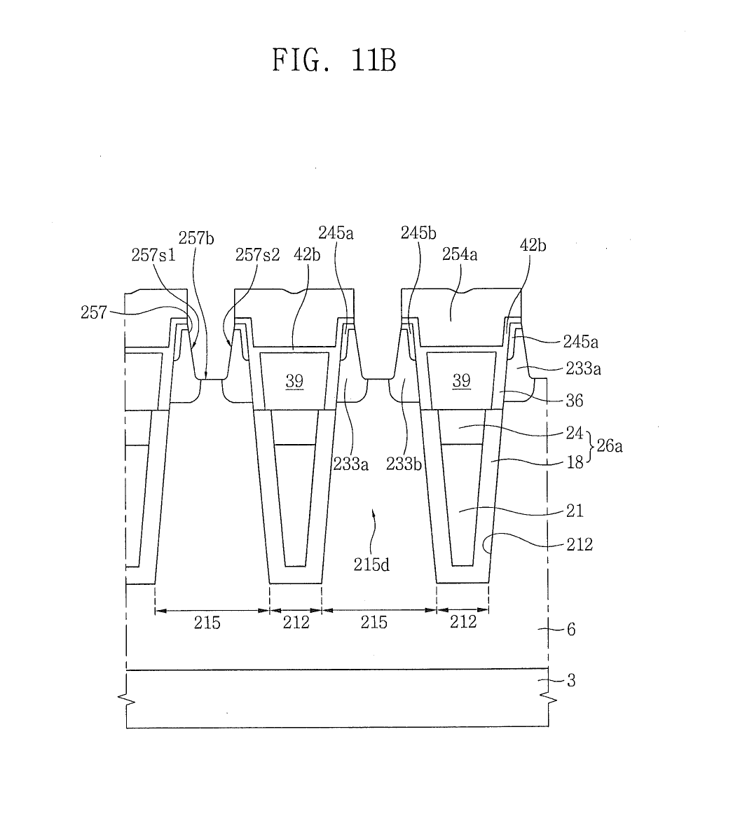

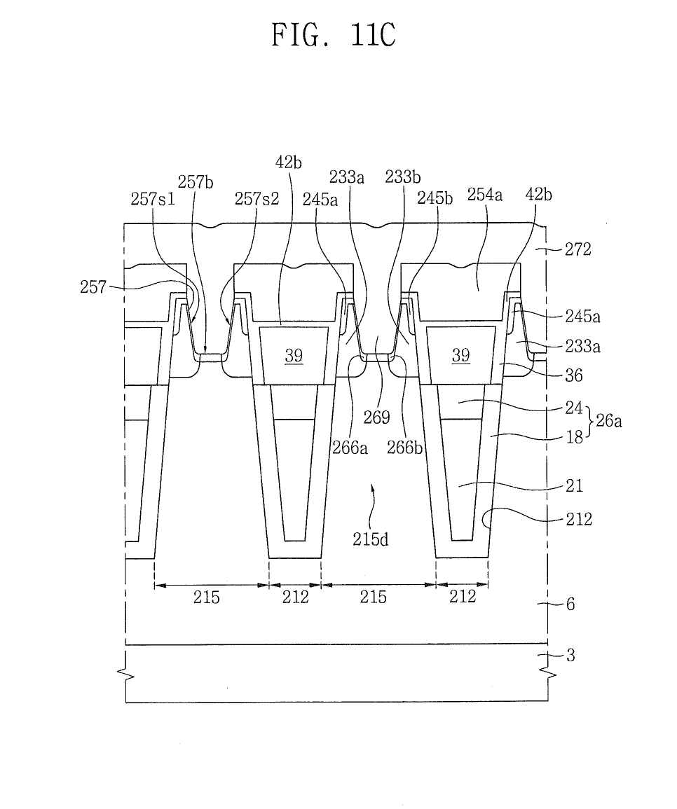

Next, an exemplary embodiment of a method of fabricating the semiconductor device 200a described with reference to FIGS. 5A and 5B will be described with reference to FIGS. 11A to 11C,

Referring to FIG. 11A, the semiconductor layer 6 may be formed on the semiconductor substrate 3, as described with reference to FIGS. 7A and 7B. A trench region 212 defining an active region 215 having tapered side surfaces may be formed in the semiconductor layer 6. As described with reference to FIGS. 7C to 7H, the shield conductive pattern 21 and the preliminary insulating structure 26 which partially fill the trench area 212 may be formed. As described with reference to FIG. 7I, the body impurity region 33 may be formed in an upper portion of the active region 215 by performing the body channel ion-implantation process 30. As described with reference to FIG. 7J, the insulating structure 26a may be formed by partially etching the preliminary insulating structure 26. As described with reference to FIG. 7K, the gate dielectric 36 may be formed on the exposed surface of the active region 215. Next, the process of forming the gate electrode 39 described in FIGS. 7K to 7M may be performed. Next, the insulating buffer layer 42a as described in FIG. 7O may be formed.

A source ion-implantation process may be performed with respect to a substrate having the insulating buffer layer 42a, to form a source impurity area 245 in the active region 215. The source ion-implantation process may be an angled ion-implantation process. The source impurity area 245 may include a part having a first junction depth from the upper surface of the active region 215, and a part having a second junction depth that is greater than the first junction depth from the upper surface of the active region 215.

Referring to FIG. 11B, an insulating capping layer may be formed on the substrate having the source impurity area 45. The insulating capping layer may be formed of an insulating material, such as silicon oxide.

An insulating capping pattern 254a may be formed by patterning the insulating capping layer. The insulating capping pattern 254a may overlap the gate electrode 39 and a part of the upper surface of the active region 215.

Next, an insulating buffer pattern 42b may be formed by etching the insulating buffer layer 42a under the insulating capping pattern 254a, and a groove region 257 may be formed by partially etching the active region 215. The groove region 257 may have tapered sidewalls 257s1 and 257s2, and a bottom surface 257b. First and second active protrusions spaced apart from each other by the groove region 257 may be formed on the upper portion of the active region 215.

The groove region 257 may pass through the source impurity area 245 and the body impurity region 33. The groove region 257 may pass through the part having the first junction depth from the upper surface of the active region 215 of the source impurity area 245, and the body impurity region 33.

A first source region 245a and a second source region 245b spaced apart from each other by the groove region 257 may be formed from the source impurity area 245, and a first body channel region 233a and a second body channel region 233b spaced apart from each other by the groove region 257 may be formed from the body impurity region 33.

The first and second source regions 245a and 245b may include parts having the first junction depth from the upper surface of the active region 215, and parts having the second junction depth greater than the first junction depth from the upper surface of the active region 215.

Referring to FIG. 11C, first and second body contact regions 266a and 266b, and a Schottky semiconductor region 269 substantially the same as the first and second body contact regions 66a and 66b, and the Schottky semiconductor region 69 may be formed by performing the additional ion-implantation process 63 as described in FIG. 7U.

The Schottky semiconductor region 269 may be formed in the active region 215 located between the first and second body channel regions 233a and 233b, the first body contact region 266a may be formed in a surface of the first body channel region 233a exposed by the groove region 257, and the second body contact region 266b may be formed in a surface of the second body channel region 233b exposed by the groove region 257. The Schottky semiconductor region 269 may be located between the first and second body contact regions 266a and 266b.

A front-side conductive pattern 272 filling the groove region 257 and covering the insulating capping pattern 254a may be formed,

Referring again to FIGS. 5A and 5B, the back side of the semiconductor substrate 3 may be ground to reduce the thickness of the semiconductor substrate 3. Next, a back-side conductive layer 280 may be formed on the back side 3bs of the semiconductor substrate 3 having the reduced thickness.

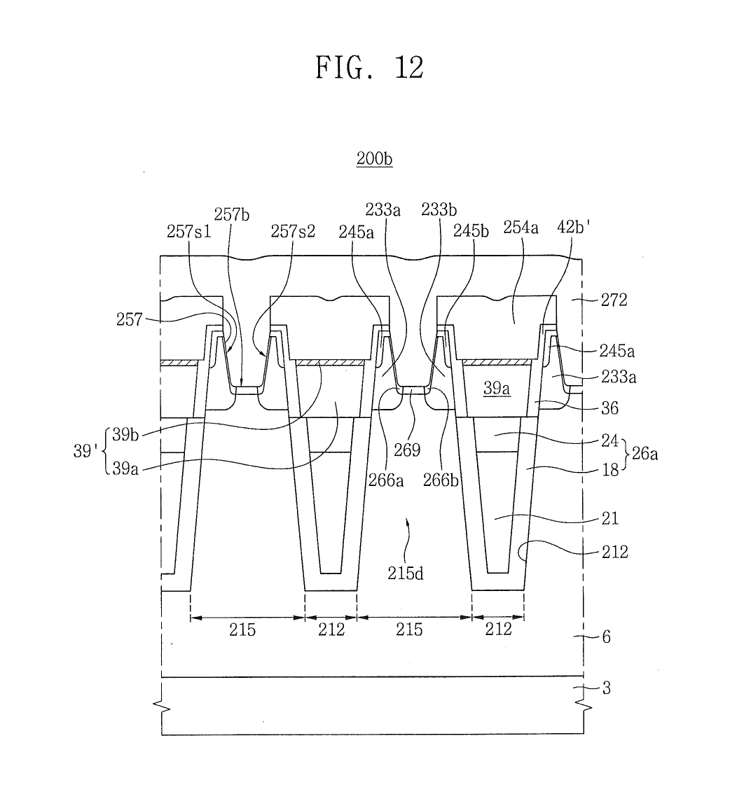

Next, an exemplary embodiment of a method of fabricating the semiconductor device 200b described with reference to FIG. 6 will be described with reference to FIG. 12.

Referring to FIG. 12, the semiconductor layer 6 may be formed on the semiconductor substrate 3, as described with reference to FIGS. 7A and 7B. A trench region 212 defining an active region 215 having tapered side surfaces may be formed in the semiconductor layer 6. As described with reference to FIGS. 7C to 7H, the shield conductive pattern 21 and the preliminary insulating structure 26 which partially fill the trench area 212 may be formed. As described with reference to FIG. 7I, the body impurity region 33 may be formed in an upper portion of the active region 215 by performing the body channel ion-implantation process 30. As described with reference to FIG. 7J, the insulating structure 26a may be formed by partially etching the preliminary insulating structure 26. As described with reference to FIG. 7K, the gate dielectric 36 may be formed on the exposed surface of the active region 215.

Next, a polysilicon pattern 39a may be formed using substantially the same method used to form as the gate electrode 39 described in FIGS. 7K to 7M.

As described with reference to FIG. 8A, after forming the polysilicon pattern 39a, an etching process may be performed to reduce the thickness of an exposed part of the gate dielectric 36. Accordingly, the thickness of the gate dielectric 36 located at a higher level than the polysilicon pattern 39a may be reduced. The gate dielectric 36 having the reduced thickness may be defined as an insulating buffer layer.

Next, a source impurity area 245 may be formed in the active region 215 by performing the source ion-implantation process as described in FIG. 11A.

Next, as in FIG. 8C, and a metal-semiconductor compound layer 39b may be formed on an exposed surface of the polysilicon pattern 39a. The metal-semiconductor compound layer 39b may be formed of a silicide, such as CoSi, NiSi, and WSi.

Next, the insulating capping pattern 254a and the groove region 257 as described in FIG. 11B may be sequentially formed. Next, the first and second body contact regions 266a and 266b, and the Schottky semiconductor region 269 as described in FIG. 11C may be formed. Next, the front-side conductive pattern 272 filling the groove region 257 may be formed.

The Schottky semiconductor region 269 is embedded between the first and second transistors TR1c and TR2c. Further, the first and second gate electrodes 39 can be configured together to provide a split-gate for the combination of the first and second transistors TR1c and TR2c outputs a single split-gate power MOSFET in some embodiments according to the invention. As appreciated by the present inventors, since the Schottky diode has a lower _{VSD} value than the body diode, dead time and power loss may be reduced.

According to some embodiments of the inventive concept, a power MOSFET device can include both a split gate arrangement and an embedded Schottky diode.

Referring again to FIG. 6, the back side 3bs of the semiconductor substrate 3 may be ground to reduce the thickness of the semiconductor substrate 3. Next, a back-side conductive layer 280 may be formed on the back side 3bs of the semiconductor substrate 3 having the reduced thickness.

FIG. 13 is a schematic circuit diagram including one of the semiconductor devices 1a, 1b, 100a, 100b, 200a, and 200b in accordance with embodiments of the inventive concept. The circuit diagram of FIG. 13 may be a part of a power conversion apparatus or power switching circuit. For example, the circuit diagram of FIG. 13 may be a part of a DC/DC converter.

Referring to FIG. 13, the circuit may include a first semiconductor substrate 310, a second semiconductor substrate 320, and a controller 340. The first semiconductor substrate 310 may be one of the semiconductor devices 1a, 1b, 100a, 100b, 200a, and 200b in accordance with embodiments of the inventive concept. The first semiconductor substrate 310 may include a transistor TR, a PN diode PND, and a Schottky diode SD. The transistor TR may be an NMOS transistor.

For example, when the first semiconductor substrate 310 is the semiconductor device 1a described with reference to FIGS. 1A and 1B, the transistor TR may be the first and second transistors TR1a and TR2a which operate as one transistor as described with reference to FIGS. 1A and 1B, the PN diode PND may be PN diodes including the P-type conductivity first and second body channel regions 33a and 33b, and the N-type conductivity drift region 15d which operate as one PN diode as described with reference to FIG. 1B, and the Schottky diode SD may be the Schottky diode SDa described with reference to FIG. 1B.

In addition, when the first semiconductor substrate 310 is the semiconductor device 100a described with reference to FIGS. 3A and 3B, the transistor TR may be the first and second transistors TR1b and TR2b which operate as one transistor as described with reference to FIGS. 3A and 3B, the PN diode PND may be PN diodes including the P-type conductivity first and second body channel regions 133a and 133b, and the N-type conductivity drift region 115d which operate like one PN diode as described with reference to FIG. 3B, and the Schottky diode SD may be the Schottky diode SDb described with reference to FIG. 3B.

In addition, when the first semiconductor substrate 310 is the semiconductor device 200a described with reference to FIGS. 5A and 5B, the transistor TR may be the first and second transistors TR1c and TR2c which operate as one transistor as described with reference to FIGS. 5A and 5B, the PN diode PND may be PN diodes including the P-type conductivity first and second body channel regions 233a and 233b, and the N-type conductivity drift region 215d which operate as one PN diode as described with reference to FIG. 5B, and the Schottky diode SD may be the Schottky diode SDc described with reference to FIG. 5B. The second semiconductor substrate 320 may include a transistor TR and a PN diode PND. The transistor TR may be an NMOS transistor.

The first semiconductor substrate 310 may be electrically connected to a ground terminal GND, and the second semiconductor substrate 320 may be electrically connected to a VDD terminal. The controller 340 may be electrically connected to the first and second semiconductor devices 310 and 320.

A drain area of a transistor of the second semiconductor substrate 320 may be electrically connected to the VDD terminal, and a source region of the transistor of the second semiconductor substrate 320 may be electrically connected to VOUT terminal.

A drain area of the transistor TR of the first semiconductor substrate 310 may be electrically connected to the source region of the transistor of the second semiconductor substrate 320, and the source region of the transistor TR of the first semiconductor substrate 310 may be electrically connected to the ground terminal GND.

A gate electrode of the transistor TR of the first semiconductor substrate 310, and a gate electrode of the transistor of the second semiconductor substrate 320 may be electrically connected to the controller 340.

The controller 340 may turn on either the transistor of the first semiconductor substrate 310 or the transistor of the second semiconductor substrate 320, and turn off the other. In this case, the controller 340 may turn off both two transistors before turning on one of the transistor TR of the first semiconductor substrate 310 and the transistor of the second semiconductor substrate 320, to avoid shoot-through currents. Likewise, the state in which both two transistors are off is defined as a dead time.

The first semiconductor substrate 310 may include the Schottky diode SD connected to the PN diode PND in parallel. Since the Schottky diode SD has a lower forward voltage than the PN diode PND, the Schottky diode SD may operate during the dead-time, whereas the PN diode PND is inoperative. Accordingly, the Schottky diode SD having relatively low forward voltage may replace the PN diode PND having relatively high forward voltage, and thereby power loss properties may be improved.

The Schottky diode SD may be a Schottky diode SDa described with reference to FIGS. 1A and 1B, the Schottky diode SDb described with reference to FIGS. 3A and 3B, the Schottky diode SDc described with reference to FIGS. 5A and 5B. The semiconductor substrate 310 may suppress leakage current generated in the Schottky diode SD. For example, when the semiconductor substrate 310 is the semiconductor device 1a described with reference to FIGS. 1A and 1B, the Schottky semiconductor region 69 of the Schottky diode SDa may be disposed between the first and second body channel regions 33a and 33b, and at a higher level than a bottom of the first and second body channel regions 33a and 33b. In addition, the drift region 15d located between the first and second body channel regions 33a and 33b, and under the Schottky semiconductor region 69 may be fully depleted, and the fully depleted region may suppress leakage current of the Schottky diode SDa.

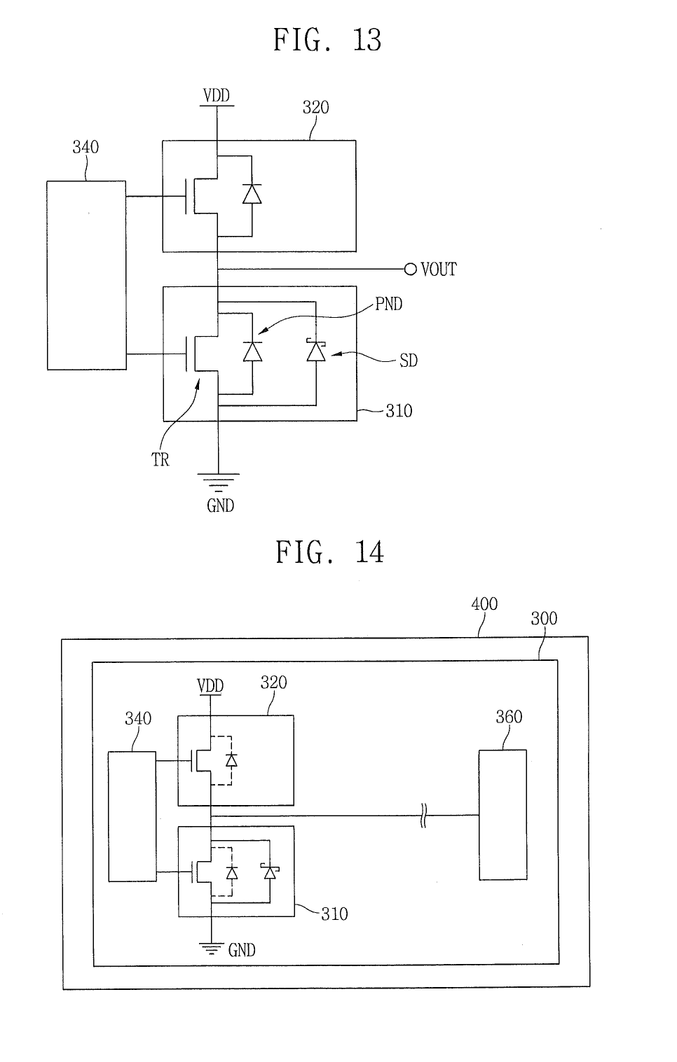

FIG. 14 is a schematic diagram showing an electronic system 400 including the circuit in FIG. 13.

Referring to FIG. 14, the electronic system 400 may include the first and second semiconductor substrates 310 and 320, and the controller 340. In addition, the electronic system 400 may include an electronic component 360.

The first semiconductor substrate 310 may be formed in a single chip or a single package. Accordingly, the transistor TR, the PN diode PND, and the Schottky diode SD may be formed in a single chip or a single package. In addition, the second semiconductor substrate 320 may be formed in a single chip or single package spaced apart from the first semiconductor substrate 310. Further, the controller 340 may be formed in a separate single chip or a single package. The electronic component 360 may be a memory or non-memory semiconductor.

The first semiconductor substrate 310, the second semiconductor substrate 320, the controller 340, and the electronic component 360 may be disposed on a board 300, and electrically connected to each other.

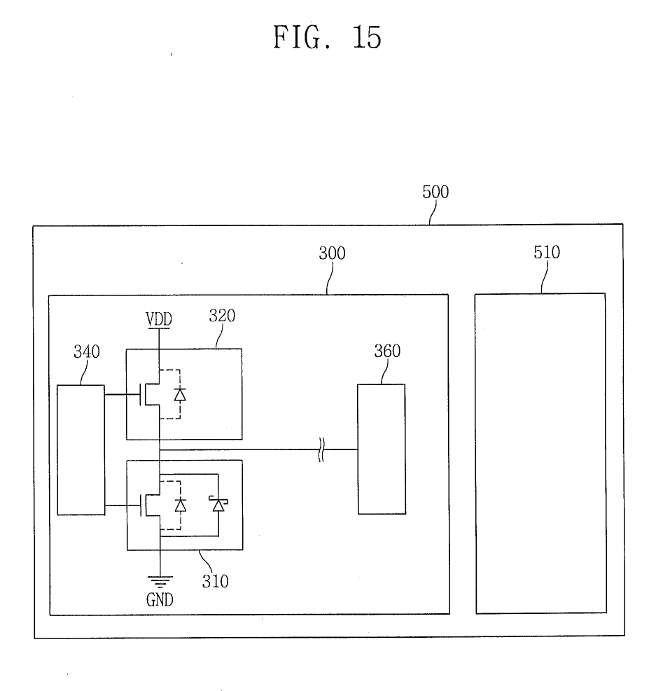

An electronic system 500 including the first and second semiconductor devices 310 and 320, and the controller 340 will be described with reference to FIG. 15.

Referring to FIG. 15, the electronic system 500 may include the first semiconductor substrate 310, the second semiconductor substrate 320, the controller 340, and the electronic component 360 as described in FIG. 13. The first semiconductor substrate 310, the second semiconductor substrate 320, the controller 340, and the electronic component 360 may be disposed on a board 300, and electrically connected to each other. The electronic system 500 may include a display apparatus 510. The display apparatus 510 may be a display of a computer system, or a display of a portable electronic apparatus. For example, the display apparatus 510 may be a monitor connected to a desktop computer, or a monitor of a laptop computer. Otherwise, the display apparatus 510 may be a display apparatus of a tablet PC, a smart phone, a portable communication system, or a portable electronic system capable of internet web surfing.

According to embodiments of the inventive concept, a semiconductor device including a transistor, a PN diode, and a Schottky diode may be provided. The semiconductor device may be formed in a single chip. Since a Schottky semiconductor region configured as a Schottky diode is disposed in an active region for forming the transistor, the area which the Schottky diode occupies in an electronic system including the semiconductor device, may be minimized.

In addition, according to embodiments of the inventive concept, the active region located under the Schottky semiconductor region may be fully depleted. Accordingly, the fully depleted region formed under the Schottky semiconductor region may suppress leakage current generated by the Schottky diode.

Further, according to embodiments of the inventive concept, the semiconductor device may be used as a part of a power application circuit or power supply set. For example, the semiconductor device may be used as a part of a DC/DC converter. Likewise, since the semiconductor device having the Schottky diode thereinside has a lower VSD value than the PN diode, resulting in reducing dead time and power loss of the DC/DC converter.

Further, according to embodiments of the inventive concept, the transistor of the semiconductor device may include a source region having a bottom surface located at a higher level near a trench region than near the trench region. The area of a body contact region located under the source region may increase due to the source region, and therefore a body contact resistance between the body contact region, and a conductive pattern forming an ohmic contact with the body contact region, may decrease.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

1. A semiconductor device, comprising:
a semiconductor substrate;
an epi-semiconductor layer disposed on the semiconductor substrate;
trenches disposed in the epi-semiconductor layer defining an active region between the trenches;
a groove region disposed in an upper surface of the active region and separating first and second active protrusions of the active region;
a gate structure disposed in each of the trenches;
a front-side conductive pattern in the groove region;
a first conductivity-type drift region, first and second body channel regions, and first and second source regions configured to form a transistor with the gate structure, wherein the first conductivity-type drift region is disposed in the active region of the epi-semiconductor layer, wherein the first and second body channel regions have a second conductivity-type different from the first conductivity-type and are spaced apart from each other, and wherein the first and second source regions have the first conductivity-type and are spaced apart from each other on opposite sides of the groove region; and
a Schottky semiconductor region having the first conductivity-type disposed between the first and second body channel regions in the groove region and in the active region under a bottom surface of the groove region, and configuring a Schottky diode with the front-side conductive pattern.

2. The semiconductor device of claim 1, wherein the Schottky semiconductor region includes 13th and 15th group elements of the long-form Periodic Table, and an amount per unit volume of the 15th group element is greater than that of the 13th group element in the Schottky semiconductor region, and
wherein the drift region adjacent to the Schottky semiconductor region includes the amount per unit volume of the 15th group element that is in the Schottky semiconductor region, and the drift region includes a higher majority carrier concentration than in the Schottky semiconductor region.

3. The semiconductor device of claim 1, wherein the first source region is disposed in the first active protrusion, and the second source region is disposed in the second active protrusion, and
wherein bottoms of the first and second source regions are located at a higher level nearer to the groove region than nearer to the trenches.

4. The semiconductor device of claim 1, wherein the first and second body channel regions are disposed on the drift region,
the first source region is disposed on the first body channel region,
the second source region is disposed on the second body channel region,
the first and second body channel regions comprise P conductivity-type, and
the drift region, the Schottky semiconductor region, and the first and second source regions comprise N conductivity-type.

5. The semiconductor device of claim 4, wherein the Schottky semiconductor region includes 13th and 15th group elements of the long-form Periodic Table, and an amount per unit volume of the 15th group element is greater than that of the 13th group element in the Schottky semiconductor region,
wherein the first and second body channel regions include the 13th and the 15th group elements of the long-form Periodic Table, and an amount per unit volume of the 15th group element in the first and second body channel regions is less than that of the 13th group element in the first and second body channel regions, and
wherein the drift region adjacent to the first and second body channel regions and the Schottky semiconductor region, the first and second body channel regions, and the Schottky semiconductor region each include an equal amount per unit volume of the 15th group element.

6. The semiconductor device of claim 1, further comprising:
a first body contact region in the groove region disposed in the active region between the conductive pattern and the first body channel region; and
a second body contact region in the groove region disposed between the conductive pattern and the second body channel region, and spaced apart from the first body contact region on opposite sides of the groove region,
wherein the first and second body contact regions have a higher majority carrier concentration than in the first and second body channel regions adjacent to the first and second body contact regions.

7. The semiconductor device of claim 6, wherein the front-side conductive pattern provides ohmic contact with the first and second body contact regions and with the first and second source regions.

8.-18. (canceled)

19. A method of fabricating a semiconductor device, comprising:
forming a first conductivity-type semiconductor layer on a semiconductor substrate;
forming trenches in the semiconductor layer to define an active region between the trenches;
forming a shield conductive pattern and a preliminary insulating structure surrounding the shield conductive pattern in each of the trenches, wherein the preliminary insulating structure is located at a lower level than an upper surface of the active region and partially fills the trenches;
forming a body impurity region having a second conductivity-type different from the first conductivity-type by performing a body channel ion-implantation process to an upper portion of the active region,
forming an insulating structure by partially etching the preliminary insulating structure after forming the body impurity region;
forming a gate structure on the insulating structure;
forming a first conductivity-type source impurity region in the upper portion of the active region, and a groove region sequentially passing through the source impurity region and the body impurity region after forming the gate structure, wherein the groove region has a tapered sidewall, the source impurity region includes first and second source regions spaced apart from each other on opposite sides of the groove region, and the body impurity region includes first and second body channel regions spaced apart from each other on the opposite sides of the groove region; and
forming a front-side conductive pattern filling the groove region.

20. The method of claim 19, further comprising forming a Schottky semiconductor region in the active region under a bottom surface of the groove region by performing an additional ion-implantation process, before forming the front-side conductive pattern,
wherein the Schottky semiconductor region is formed by a junction of the Schottky semiconductor region and the first and second body channel regions, and is at a higher level than bottom surfaces of the first and second body channel regions.

21. The method of claim 20, wherein the semiconductor layer includes a 15th group element of the long-form Periodic Table and has N conductivity-type, and
the additional ion-implantation process comprises injecting a 13th group element of the long-form Periodic Table into the active region under the bottom surface of the groove region.

22. The method of claim 20, wherein the additional ion-implantation process comprises injecting impurity ions in a direction perpendicular to the semiconductor substrate.

23. The method of claim 19, wherein the body channel ion-implantation process comprises injecting impurity ions in a direction that is angled relative to a surface of the semiconductor substrate through which the injecting is performed.

24. The method of claim 19, further comprising forming an insulating capping pattern on the gate structure after forming the source impurity region and before forming the groove region,
wherein the insulating capping pattern comprises an etch mask used in an etching process for forming the groove region.

25. The method of claim 19, wherein the source impurity region is formed by performing a source ion-implantation process in which a 15th group element of the long-form Periodic Table is injected in a direction that is angled relative to a surface of the semiconductor substrate through which the ion-implantation process is performed.

26. A semiconductor device, comprising:
first and second vertical channel power MOSFET transistors arranged in a split-gate configuration in a semiconductor substrate;
a groove in an active region between the first and second vertical channel power MOSFET transistors;
a conductive pattern in the groove on the active region, the conductive pattern comprising a source contact for the first and second vertical channel power MOSFET transistors; and
a vertical Schottky semiconductor region embedded in the groove beneath the conductive pattern between the vertical channel power MOSFET transistors.

27. The semiconductor device according to claim 26 wherein the first and second vertical channel power MOSFET transistors arranged in the split-gate configuration operate as a single transistor.

28. The semiconductor device according to claim 26 further comprising:
a drain contact for the first and second vertical channel power MOSFET transistors beneath the groove opposite the source contact.

29. The semiconductor device according to claim 26 wherein the vertical Schottky semiconductor region and the conductive pattern comprise an embedded vertical Schottky diode forming a junction at a bottom of the groove with the active region.

30. The semiconductor device according to claim 26 wherein the vertical Schottky semiconductor region includes 13th and 15th group elements of the long-form Periodic Table, and an amount per unit volume of the 15th group element is greater than that of the 13th group element in the vertical Schottky semiconductor region.

31. The semiconductor device according to claim 29 further comprising:
first and second source regions for the respective first and second vertical channel power MOSFET transistors, the first and second source regions on opposite sides of the groove, wherein the source regions include lower most implanted regions that are above the junction.
